(19) United States
(12) Patent Application Publication
(10) Pub. No.: US 2007/0158729 A1
(43) Pub. Date: Jul. 12, 2007

(54) Thin film transistor array panel and method of manufacture

(76) Inventors: Young-Chol Yang, Seongnam-si (KR); Dae-Jin Park, Incheon-si (KR); Ji-Suk Lim, Daejeon-si (KR); Yong-Gi Park, Siheung-si (KR)

Correspondence Address: MACPHERSON KWOK CHEN & HEID LLP, 2033 GATEWAY PLACE, SUITE 400, SAN JOSE, CA, 95110, US

(21) Appl. No.: 11/648,771

(22) Filed: Dec. 28, 2006

(30) Foreign Application Priority Data
Dec. 29, 2005 (KR) 10-2005-0133513
Oct. 17, 2006 (KR) 10-2006-0100745

(51) Int. Cl. H01L 29/94

(52) U.S. Cl. 257/306

(57) ABSTRACT

A TFT array panel for a display has a gate insulating layer with substantially the same dielectric constant as the passivation layer and may be thicker than the passivation layer, while the storage capacitor includes a pixel electrode and a storage electrode overlapping each other along with the passivation layer sandwiched therebetween such that the storage capacitor has a higher capacitance than known storage capacitors even though the storage conductors have the same area as before.

### CROSS-REFERENCE TO RELATED APPLICATION

This application claims priority to and the benefit of Korean Patent Application No. 10-2005-0133513 and 10-2006-0100745 filed in the Korean Intellectual Property Office on Dec. 29, 2005 and Oct. 17, 2006, the entire contents of which are incorporated herein by reference.

### BACKGROUND OF THE INVENTION

1. Field of the Invention

The present invention relates to a thin film transistor array panel and a manufacturing method thereof.

2. Description of the Related Art

Flat panel displays such as a liquid crystal display (LCD) and an organic light emitting diode (OLED) display include several pairs of field generating electrodes and electro-optical active layers interposed therebetween. The LCD includes a liquid crystal layer as an electro-optical active layer, and the OLED includes an organic emission layer as the electro-optical active layer.

One electrode of a pair of field generating electrodes, i.e., a pixel electrode, is commonly connected to a switching element for transmitting electrical signals to the pixel electrode, and the electro-optical active layer converts the electrical signals to optical signals to display an image.

A thin film transistor (TFT) having three terminals is used for the switching element in the flat panel display, and a plurality of signal lines such as gate lines and data lines are also provided on the flat panel display. The gate lines transmit signals for controlling the TFTs which apply signals from the data lines to the pixel electrodes.

In the LCD, a pixel electrode, supplied with a data voltage through a turned-on TFT, generates electric fields in cooperation with a common electrode to charge a liquid crystal capacitor. The LCD includes an additional capacitor referred to as a “storage capacitor” for enhancing the voltage storing capacity of the liquid crystal capacitor after the TFT is turned off since the pixel voltage may drop a little when the gate-on voltage is changed to the gate-off voltage. The storage capacitor helps to maintain a uniform pixel voltage.

Accordingly, an LCD benefits from having a storage capacitor with as large a capacity as possible.

### SUMMARY OF THE INVENTION

A thin film transistor array panel according to an embodiment of the present invention includes a substrate, a gate line including a gate electrode, and a storage electrode line including a storage electrode formed on the substrate, a gate insulating layer formed on the gate line, the storage electrode line, and the substrate, a semiconductor layer formed on the gate insulating layer, a data line and a drain electrode formed on the semiconductor layer and the gate insulating layer, a storage conductor formed on the gate insulating layer being made of the same layer as the data line and separated therefrom, and electrically connected to the storage electrode using a connecting member, a passivation layer formed on the data line, the drain electrode, and the storage conductor, and a transparent electrode formed on the passivation layer and connected to the drain electrode.

The gate insulating layer may be thicker than the passivation layer, and the transparent electrode and the storage conductor overlap each other to form a storage capacitor along with the passivation layer sandwiched therebetween.

The storage conductor may be supplied with a storage voltage through the storage electrode.

The passivation layer may have a hole exposing a portion of the storage conductor.

The TFT array panel may further include an organic insulator formed on a portion of the transparent electrode, and a reflective electrode formed on the organic insulator.

The reflective electrode may be physically and electrically connected to the transparent electrode at the edge of the organic insulator.

The storage conductor may be disposed in a region including the reflective electrode.

A TFT array panel according to another embodiment of the present invention includes a substrate, a gate line including a gate electrode and formed on the substrate, a gate insulating layer formed on the gate line and the substrate, a semiconductor layer formed on the gate insulating layer, a data line, a drain electrode, and a storage electrode line including a storage electrode formed on the semiconductor layer and the gate insulating layer, a passivation layer formed on the data line, the drain electrode, and the storage electrode line, and a transparent electrode formed on the passivation layer and connected to the drain electrode.

The storage electrode line may extend substantially parallel to the data line.

The gate insulating layer may be thicker than the passivation layer, and the transparent electrode and the storage electrode line including the storage electrode overlap each other to form a storage capacitor along with the passivation layer sandwiched therebetween.

The storage electrode line may be supplied with a storage voltage.

The TFT array panel may further include an organic insulator formed on a portion of the transparent electrode and a reflective electrode formed on the organic insulator.

The reflective electrode may be physically and electrically connected to the transparent electrode at the edge of the organic insulator.

The storage conductor may be disposed in a region including the reflective electrode.

A method of manufacturing a TFT array panel according to another embodiment of the present invention includes forming a gate line including a gate electrode and a storage electrode line including a storage electrode on a substrate, forming a gate insulating layer on the gate line, the storage electrode line and the substrate, forming a semiconductor layer on the gate insulating layer, forming a data line, a drain electrode, and a storage conductor on the gate insulating layer and the semiconductor layer, forming a passivation layer on the data line, the drain electrode, and the storage conductor, and forming a pixel electrode connected to the drain electrode on the passivation layer.

The method may further include forming a hole in the passivation layer exposing the storage conductor, forming a contact hole in the gate insulating layer exposing the storage electrode, and forming a connecting member electrically connecting the storage conductor to the storage electrode through the contact hole.

Forming of the pixel electrode and forming the connecting member may be performed simultaneously.

A method of manufacturing a TFT array panel according to another embodiment of the present invention includes forming a gate line including a gate electrode on a substrate, forming a gate insulating layer on the gate line and the substrate, forming a semiconductor layer on the gate insulating layer, forming a data line, a drain electrode, and a storage electrode line including a storage electrode on the gate insulating layer and the semiconductor layer, forming a passivation layer on the data line, the drain electrode, and the storage electrode line, and forming a pixel electrode connected to the drain electrode on the passivation layer.

The gate insulating layer may be thicker than the passivation layer, and the pixel electrode and the storage electrode line including the storage electrode overlap each other to form a storage capacitor along with the passivation layer sandwiched therebetween.

The method may further include forming an organic insulator on a portion of the pixel electrode and forming a reflective electrode on the organic insulator.

A TFT array panel according to another embodiment of the present invention includes a substrate, a gate line including a gate electrode, and a storage electrode line including a storage electrode formed on the substrate, a gate insulating layer formed on the gate line, the storage electrode line, and the substrate and having a contact hole exposing the storage electrode, a semiconductor layer formed on the gate insulating layer, a data line and a drain electrode formed on the semiconductor layer and the gate insulating layer, a storage conductor formed on the gate insulating layer, being made of the same layer to the data line and separated therefrom, and electrically connected to the storage electrode through the contact hole of the gate insulating layer, a passivation layer formed on the data line, the drain electrode, and the storage conductor, and a pixel electrode formed on the passivation layer and connected to the drain electrode.

The storage conductor may be supplied with a storage voltage through the storage electrode.

The passivation layer may have a contact hole exposing the drain electrode, and the pixel electrode may be electrically connected to the drain electrode through the contact hole.

A manufacturing method of a TFT array panel according to another embodiment of the present invention includes forming a gate line including a gate electrode and a storage electrode line including a storage electrode on a substrate, forming a gate insulating layer on the gate line, the storage electrode line and the substrate, depositing an intrinsic amorphous silicon layer on the gate insulating layer, depositing an extrinsic amorphous silicon layer on the intrinsic amorphous silicon layer, patterning the extrinsic amorphous silicon layer and the intrinsic amorphous silicon layer along with the gate insulating layer to form an extrinsic semiconductor pattern and an intrinsic semiconductor pattern and a first contact hole exposing a portion of the storage electrode in the gate insulating layer, simultaneously forming a data line and a drain electrode on the gate insulating layer and the extrinsic semiconductor pattern and a storage conductor connected to the storage electrode through the first contact hole, forming a passivation layer having a second contact hole exposing the drain electrode on the data line, the drain electrode, and the storage conductor, and forming a pixel electrode connected to the drain electrode through the second contact hole on the passivation layer.

A TFT array panel according to another embodiment of the present invention includes a substrate, a gate line including a gate electrode, and a storage electrode line including a storage electrode formed on the substrate, a gate insulating layer formed on the gate line, the storage electrode line, and the substrate and having a contact hole exposing the whole storage electrode, a semiconductor layer formed on the gate insulating layer, a data line and a drain electrode formed on the semiconductor layer and the gate insulating layer, a passivation layer formed on the data line and the drain electrode, and a pixel electrode connected to the drain electrode and formed on the passivation layer, wherein the pixel electrode and the storage electrode overlap each other to form a storage capacitor along with the passivation layer sandwiched therebetween.

The passivation may have a double-layered structure including a lower layer and an upper layer, and the upper layer may be thicker than the lower layer.

The upper layer of the passivation layer may be eliminated over the storage electrode.

The lower layer may include an inorganic insulator, and the upper layer may include an organic insulator.

A method of manufacturing a TFT array panel according to another embodiment of the present invention includes forming a gate line including a gate electrode and a storage electrode line including a storage electrode on a substrate, forming a gate insulating layer on the gate line, the storage electrode line and the substrate, depositing an intrinsic amorphous silicon layer on the gate insulating layer, depositing an extrinsic amorphous silicon layer on the intrinsic amorphous silicon layer, patterning the extrinsic amorphous silicon layer and the intrinsic amorphous silicon layer along with the gate insulating layer to form an extrinsic semiconductor pattern and an intrinsic semiconductor pattern and a first contact hole exposing a portion of the storage electrode in the gate insulating layer, forming a data line and a drain electrode on the gate insulating layer and the extrinsic semiconductor pattern, forming a passivation layer having a second contact hole exposing the drain electrode on the data line and the drain electrode, and forming a pixel electrode connected to the drain electrode through the second contact hole on the passivation layer.

Forming of the passivation layer may include depositing a lower passivation layer on the substrate, depositing an upper passivation layer on the lower passivation layer, forming photoresist patterns having a position-dependent thickness and exposing a portion of the upper passivation layer, etching the upper passivation layer, the lower passivation layer, and gate insulating layer to form a second contact hole, a third contact hole, and a fourth contact hole exposing the gate line, the data line, and the drain electrode, respectively, reducing the height of the photoresist patterns to expose the upper passivation layer over the storage electrode, etching the upper passivation layer using the reduced photoresist patterns as a mask to eliminate the upper passivation layer, and eliminating the reduced photoresist patterns, and the thickness of the gate insulating layer may be thicker than that of the lower passivation layer.

### BRIEF DESCRIPTION OF THE DRAWINGS

FIG. 1 is a layout view of a TFT array panel according to an embodiment of the present invention;

FIG. 2 and FIG. 3 are sectional views of the TFT array panel shown in FIG. 1 taken along the lines II-II and III-III;

FIG. 4, FIG. 7, FIG. 10, FIG. 13, and FIG. 16 are layout views of the TFT array panel in intermediate steps of a manufacturing method thereof according to an embodiment of the present invention;

FIG. 5 and FIG. 6 are sectional views of the TFT array panel shown in FIG. 4 taken along the lines V-V and VI-VI;

FIG. 8 and FIG. 9 are sectional views of the TFT array panel shown in FIG. 7 taken along the lines VIII-VIII and IX-IX;

FIG. 11 and FIG. 12 are sectional views of the TFT array panel shown in FIG. 10 taken along the lines XI-XI and XII-XII;

FIG. 14 and FIG. 15 are sectional views of the TFT array panel shown in FIG. 13 taken along the lines XIV-XIV and XV-XV;

FIG. 17 and FIG. 18 are sectional views of the TFT array panel shown in FIG. 16 taken along the lines XVII-XVII and XVIII-XVIII;

FIG. 19 is a layout view of a TFT array panel according to another embodiment of the present invention;

FIG. 20 and FIG. 21 are sectional views of the TFT array panel shown in FIG. 19 taken along the lines XX-XX and XXI-XXI;

FIG. 22, FIG. 25, FIG. 28, and FIG. 31 are layout views of the TFT array panel in intermediate steps of a manufacturing method thereof according to another embodiment of the present invention;

FIG. 23 and FIG. 24 are sectional views of the TFT array panel shown in FIG. 22 taken along the lines XXIII-XXIII and XXIV-XXIV;

FIG. 26 and FIG. 27 are sectional views of the TFT array panel shown in FIG. 25 taken along the lines XXVI-XXVI and XXVII-XXVII;

FIG. 29 and FIG. 30 are sectional views of the TFT array panel shown in FIG. 28 taken along the lines XXIX-XXIX and XXX-XXX;

FIG. 32 and FIG. 33 are sectional views of the TFT array panel shown in FIG. 31 taken along the lines XXXII-XXXII and XXXIII-XXXIII;

FIG. 34 is a layout view of a TFT array panel according to another embodiment of the present invention;

FIG. 35 and FIG. 36 are sectional views of the TFT array panel shown in FIG. 34 taken along the lines XXXV-XXXV and XXXVI-XXXVI;

FIG. 37 is a layout view of a TFT array panel according to another embodiment of the present invention;

FIG. 38 and FIG. 39 are sectional views of the TFT array panel shown in FIG. 37 taken along the lines XXXVIII-XXVIII and XXXIX-XXXIX;

FIG. 40 is a layout view of a TFT array panel according to another embodiment of the present invention;

FIG. 41 and FIG. 42 are sectional views of the TFT array panel shown in FIG. 40 taken along the lines XLI-XLI and XLII-XLII;

FIG. 43, FIG. 46, FIG. 49, and FIG. 52 are layout views of the TFT array panel in intermediate steps of a manufacturing method thereof according to another embodiment of the present invention;

FIG. 44 and FIG. 45 are sectional views of the TFT array panel shown in FIG. 43 taken along the lines XLIV-XLIV and XLV-XLV;

FIG. 47 and FIG. 48 are sectional views of the TFT array panel shown in FIG. 46 taken along the lines XLVII-XLVII and XLVIII-XLVIII;

FIG. 50 and FIG. 51 are sectional views of the TFT array panel shown in FIG. 49 taken along the lines L-L and LI-LI;

FIG. 53 and FIG. 54 are sectional views of the TFT array panel shown in FIG. 52 taken along the lines LIII-LIII and LIV-LIV;

FIG. 55 is a layout view of a TFT array panel according to another embodiment of the present invention;

FIG. 56 and FIG. 57 are sectional views of the TFT array panel shown in FIG. 55 taken along the lines LVI-LVI and LVII-LVII;

FIG. 58, FIG. 61, FIG. 64, and FIG. 67 are layout views of the TFT array panel in intermediate steps of a manufacturing method thereof according to another embodiment of the present invention;

FIG. 59 and FIG. 60 are sectional views of the TFT array panel shown in FIG. 58 taken along the lines LIX-LIX and LX-LX;

FIG. 62 and FIG. 63 are sectional views of the TFT array panel shown in FIG. 61 taken along the lines LXII-LXII and LXIII-LXIII;

FIG. 65 and FIG. 66 are sectional views of the TFT array panel shown in FIG. 64 taken along the lines LXV-LXV and LXVI-LXVI;

FIG. 68 and FIG. 69 are sectional views of the TFT array panel shown in FIG. 67 taken along the lines LXVIII-LXVIII and LXIX-LXIX;

FIG. 70 is a layout view of a TFT array panel according to another embodiment of the present invention;

FIG. 71 and FIG. 72 are sectional views of the TFT array panel shown in FIG. 70 taken along the lines LXXI-LXXI and LXXII-LXXII; and

FIG. 73 to FIG. 82 are sectional views of the TFT array panel shown in FIG. 70 to FIG. 72 in intermediate steps of a manufacturing method thereof according to another embodiment of the present invention.

### DETAILED DESCRIPTION OF THE EMBODIMENTS

Exemplary embodiments of the present invention will hereinafter be described in detail with reference to the accompanying drawings.

In the drawings, the thickness of layers, films, panels, regions, etc., are exaggerated for clarity. It will be understood that when an element such as a layer, film, region, or substrate is referred to as being “on” another element, it can be directly on the other element or intervening elements may also be present. In contrast, when an element is referred to as being “directly on” another element, there are no intervening elements present.

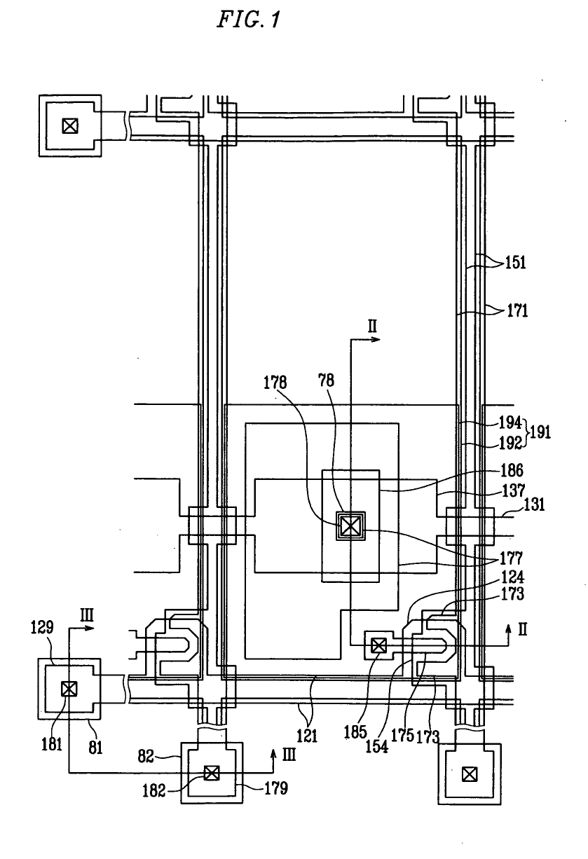

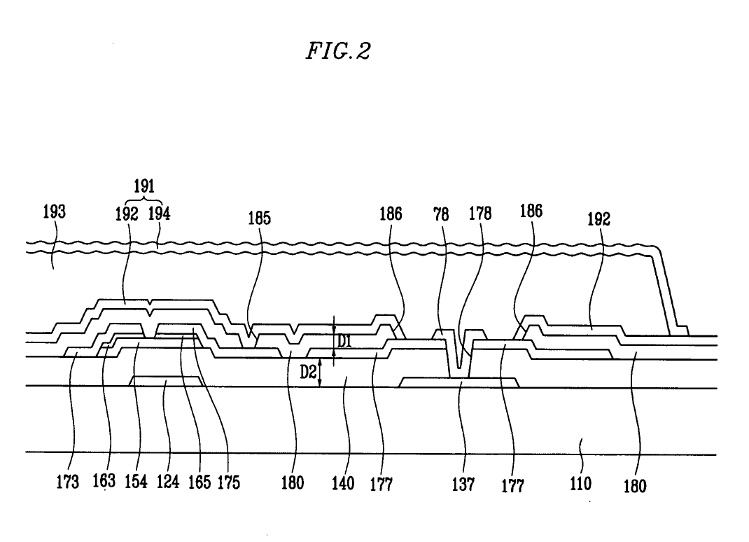

First, a thin film transistor (TFT) array panel according to an embodiment of the present invention will be described in detail with reference to FIG. 1 to FIG. 3.

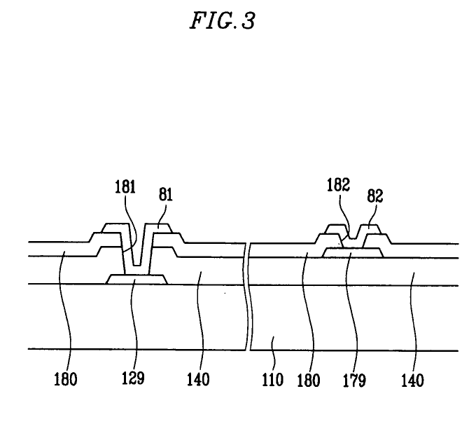

FIG. 1 is a layout view of a TFT array panel according to an embodiment of the present invention, and FIG. 2 and FIG. 3 are sectional views of the TFT array panel shown in FIG. 1 taken along the lines II-II and III-III.

A plurality of gate lines 121 and a plurality of storage electrode lines 131 are formed on an insulating substrate 110 such as transparent glass or plastic.

Each of the gate lines 121 includes a gate electrode 124 projecting downward and an end portion 129 having a large area for contact with another layer or an external driving circuit. A gate driving circuit (not shown) for generating the gate signals may be mounted on a flexible printed circuit (FPC) film (not shown), which may be attached to the substrate 110, directly mounted on the substrate 110, or integrated onto the substrate 110. The gate lines 121 may extend to be connected to a driving circuit that may be integrated on the substrate 110.

The storage electrode lines 131 are supplied with a predetermined voltage and extend substantially parallel to the gate lines 121. Each of the storage electrode lines 131 is disposed between two adjacent gate lines 121 and it is close to one of the two adjacent gate lines 121. Each of the storage electrode lines 131 includes a storage electrode 137 expanding upward and downward. However, the storage electrode lines 131 may have various shapes and arrangements.

The gate lines 121 and the storage electrode lines 131 may be made of an Al-containing metal such as Al and an Al alloy, a Ag-containing metal such as Ag and an Ag alloy, a Cu-containing metal such as Cu and a Cu alloy, a Mo-containing metal such as Mo and a Mo alloy, Cr, Ta, or Ti. However, they may have a multi-layered structure including two conductive films (not shown) having different physical characteristics. One of the two films may be made of a low resistivity metal including an Al-containing metal, an Ag-containing metal, and a Cu-containing metal for reducing signal delay or voltage drop. The other film may be made of a material such as a Mo-containing metal, Cr, Ta, or Ti, which has good physical, chemical, and electrical contact characteristics with other materials such as indium tin oxide (ITO) or indium zinc oxide (IZO). Good examples of the combination of the two films are a lower Cr film and an upper Al (alloy) film, and a lower Al (alloy) film and an upper Mo (alloy) film. However, the gate lines 121 and the storage electrode lines 131 may be made of various metals or conductors.

The lateral sides of the gate lines 121 and the storage electrode lines 131 are inclined relative to a surface of the substrate 110, and the inclination angle thereof ranges from about 30 to 80 degrees.

A gate insulating layer 140 preferably made of silicon nitride (SiNx) or silicon oxide (SiOx) is formed on the gate lines 121 and the storage electrode lines 131. The gate insulating layer 140 has a plurality of contact holes 178 exposing a portion of the storage electrodes 137.

A plurality of semiconductor stripes 151 preferably made of hydrogenated amorphous silicon (abbreviated to “a-Si”) or polysilicon are formed on the gate insulating layer 140. Each of the semiconductor stripes 151 extends substantially in the longitudinal direction and includes projections 154 branched out toward the gate electrodes 124. The semiconductor stripes 151 become wide near the gate lines 121 and the storage electrode lines 131 such that the semiconductor stripes 151 cover large areas of the gate lines 121 and the storage electrode lines 131.

A plurality of ohmic contact stripes and islands 161 and 165 are formed on the semiconductor stripes 151. The ohmic contacts 161 and 165 are preferably made of n+ hydrogenated a-Si heavily doped with an n-type impurity such as phosphorous, or they may be made of silicide. Each of the ohmic contact stripes 161 includes a plurality of projections 163, and the projections 163 and the ohmic contact islands 165 are located in pairs on the projections 154 of the semiconductor stripes 151.

The lateral sides of the semiconductor stripes 151 and the ohmic contacts 161 and 165 are inclined relative to the surface of the substrate 110, and the inclination angles thereof are preferably in a range of about 30 to 80 degrees.

A plurality of data lines 171, a plurality of drain electrodes 175, and a plurality of storage conductors 177 are formed on the ohmic contacts 161, 163, and 165 and the gate insulating layer 140.

The data lines 171 transmit data signals and extend substantially in the longitudinal direction to intersect the gate lines 121 and the storage electrode lines 131. Each data line 171 includes source electrode 173 projecting toward the gate electrode 124, and an end portion 179 having a large area for contact with another layer or an external driving circuit. A data driving circuit (not shown) for generating the data signals may be mounted on a FPC film (not shown), which may be attached to the substrate 110, directly mounted on the substrate 110, or integrated onto the substrate 110.

The data lines 171 may extend to be connected to a driving circuit that may be integrated on the substrate 110.

The drain electrodes 175 are separated from the data lines 171, and are disposed opposite the source electrodes 173 with respect to the gate electrodes 124. Each of the drain electrodes 175 includes a wide end portion and a narrow end portion. The wide end portion is connected to a transparent electrode 192 through a contact hole 185 and the narrow end portion is partly enclosed by a source electrode 173.

A gate electrode 124, a source electrode 173, and a drain electrode 175 along with a projection 154 of a semiconductor stripe 151 form a TFT having a channel formed in the projection 154 disposed between the source electrode 173 and the drain electrode 175.

The storage conductor 177 is made of the same layer to the data line 171, it is separated from the data line 171 and the drain electrode 175, and it may have a rectangular shape with a hole in the middle corresponding to the contact hole 178 of the gate insulating layer 140. The storage conductor 177 is electrically connected to the storage electrode 137 through the contact hole 178 of the gate insulating layer 140.

The data lines 171, the drain electrodes 175, and the storage conductors 177 may be made of a refractory metal such as Mo, Cr, Ta, Ti, or alloys thereof. However, they may have a multi-layered structure including a refractory metal film (not shown) and a low resistivity conductive film (not shown). Good examples of the multi-layered structure are a double-layered structure including a lower Cr/Mo (alloy) film and an upper Al (alloy) film and a triple-layered structure of a lower Mo (alloy) film, an intermediate Al (alloy) film, and an upper Mo (alloy) film. However, the data lines 171, the drain electrodes 175, and the storage conductors 177 may be made of various metals or conductors.

The data lines 171, the drain electrodes 175, and the storage conductors have inclined edge profiles, and the inclination angles thereof range from about 30 to 80 degrees.

The ohmic contacts 161 and 165 are interposed only between the underlying semiconductor stripes 151 and the overlying conductors 171 and 175 thereon, and reduce the contact resistance therebetween. Although the semiconductor stripes 151 are narrower than the data lines 171 at most places, the width of the semiconductor stripes 151 becomes large near the gate lines 121 and the storage electrode lines 131 as described above, to smooth the profile of the surface, thereby preventing disconnection of the data lines 171. However, the semiconductor stripes 151 include some exposed portions, which are not covered with the data lines 171 and the drain electrodes 175, such as portions located between the source electrodes 173 and the drain electrodes 175.

A passivation layer 180 is formed on the data lines 171, the drain electrodes 175, the storage conductors 177, and the exposed portions of the semiconductor stripes 151. The passivation layer 180 may be made of an inorganic insulator such as silicon nitride and silicon oxide.

The passivation layer 180 has a plurality of contact holes 182 and 185 exposing the end portions 179 of the data lines 171 and the drain electrodes 175, respectively. The passivation layer 180 and the gate insulating layer 140 have a plurality of contact holes 181 exposing the end portions 129 of the gate lines 121. The passivation layer 180 has a plurality of holes 186 exposing a portion of the storage conductors 177.

A plurality of transparent electrodes 192 and a plurality of contact assistants 81 and 82 are formed on the passivation layer 180. A plurality of connecting members 78 are formed on storage conductors 177 exposed through holes 186 and on the storage electrodes 137 that are exposed through contact holes 178.

As described above, storage conductor 177 is electrically connected to storage electrode 137 through contact hole 178 using connecting member 78 formed on storage conductor 177 exposed through the hole 186 and the storage electrode 137 exposed through the contact hole 178. Accordingly, the connecting member 78 makes the storage conductor 177 electrically connected to storage electrode 137 such that the storage conductor 177 is supplied with a storage voltage.

A plurality of organic insulators 187 are formed on the transparent electrodes 192, the storage conductors 177, the connecting members 78, and the passivation layer 180. The organic insulator 187 may have photosensitivity and a good planarization characteristic.

The organic insulator 187 has an embossed surface. Each reflective electrode 194 is curved along the embossed surface of the organic insulator 187 to have protrusion patterns and depression patterns. The protrusion patterns and depression patterns of the reflective electrode 194 enhance reflective efficiency. Each organic insulator 187 may be disposed on a portion of each transparent electrode 192. The organic insulator 187 is eliminated in the regions of the end portions 129 of the gate lines 121, and the end portions 179 of the data lines 171.

The pixel electrodes 191 include the transparent electrodes 192 and the reflective electrodes 194 disposed on the organic insulator 187 and curved along the embossed surface of the organic insulator 187.

The transflective LCD liquid crystal display includes a transmissive area TA and a reflective area RA defined by the transparent electrodes 192 and the reflective electrodes 194, respectively.

In detail, areas disposed under and over an exposed portion of the transparent electrodes 192 from the organic insulator 187 are transmissive regions TA, and areas disposed under and over the reflective electrodes 194 are reflective regions RA.

Each storage conductor 177 is disposed in the reflective regions RA.

In the transmissive regions TA, light from a backlight unit (not shown) disposed under the TFT array panel 100 passes through the LC layer 3 to display desired images. In the reflective regions RA, external light such as sunlight or ambient light that is incident thereon passes through the common electrode panel 200 and through the LC layer 3 to reach the reflective electrodes 194. Then, the external light is reflected by the reflective electrodes 194 and passes through the LC layer 3 again, to display desired images.

The transparent electrodes 192 are preferably made of a transparent conductor such as ITO or IZO, and the reflective electrodes 194 are preferably made of a reflective conductor such as Ag, Al, Cr, or alloys thereof. However, the reflective electrodes 194 may have a double-layered structure including an upper layer (not shown) made of a low resistivity reflective metal such as Al, Ag, or alloys thereof and a lower layer (not shown) made of a metal such as Mo and a Mo alloy, Cr, Ta, or Ti, which has good physical, chemical, and electrical contact characteristics with ITO or IZO.

The reflective electrodes 194 are physically and electrically connected to the transparent electrodes 192 at the edge of the transmissive regions TA and the reflective regions RA.

The transparent electrodes 192 and the reflective electrodes 194 connected thereto are physically and electrically connected to the drain electrodes 175 through the contact holes 185 such that the pixel electrodes 191 including the transparent electrodes 192 and the reflective electrodes 194 receive data voltages from the drain electrodes 175.

The pixel electrodes 191 supplied with the data voltages generate electric fields in cooperation with a common electrode (not shown) of an opposing display panel (not shown) supplied with a common voltage, which determine the orientations of liquid crystal molecules (not shown) of a liquid crystal layer (not shown) disposed between the two electrodes. A pixel electrode 191 and the common electrode form a capacitor referred to as a “liquid crystal capacitor,” which stores applied voltages after the TFT turns off.

The transparent electrode 192 overlaps the storage conductor 177 electrically connected to the storage electrode 137 and separated by the passivation layer 180 sandwiched therebetween. The transparent electrode 192 and the storage conductor 177 electrically connected to the storage electrode 137 form an additional capacitor referred to as a “storage capacitor,” which enhances the voltage storing capacity of the liquid crystal capacitor.

The conventional LCD includes a storage capacitor formed by a pixel electrode and a storage electrode line overlapping each other along with the gate insulating layer sandwiched therebetween. However, as described above, the TFT array panel according to an embodiment of the present invention includes the storage capacitor formed by transparent electrode 192 and the storage conductor 177 overlapping each other along with the passivation layer 180 sandwiched therebetween.

Meanwhile, electrical capacity C of two conductors overlapping each other in parallel is defined by C≈εA/d. Here, ε is a dielectric constant of an insulator sandwiched between the two conductors, A is an area of the conductors overlapping each other, and d is a distance between the two conductors. If the dielectric constant of the insulator is equal, the electrical capacity increases with the area of the conductors overlapping each other and decreases with the distance between the two conductors. Accordingly, for increasing the electrical capacity C, the area of the conductors overlapping each other may be increased or the distance between the two conductors may be decreased.

In the TFT array panel according to an embodiment of the invention, the gate insulating layer 140 may have the substantially same dielectric constant as the passivation layer 180, and the thickness D1 of the gate insulating layer 140 may be thicker than the thickness D2 of the passivation layer 180. The thickness D1 of the gate insulating layer 140 may be thicker than the thickness D2 of the passivation layer 180 by about two times.

Accordingly, if the area of the conductors overlapping each other is equal, the capacitor including two conductors and the passivation layer 180 sandwiched therebetween may have a higher electrical capacity C than the capacitor including two conductors and the gate insulating layer 140 sandwiched therebetween.

As described above, the TFT array panel according to an embodiment of the present invention includes the storage capacitor including the transparent electrode 192 and the storage conductor 177 overlapping each other, and the passivation layer 180 sandwiched therebetween.

The known storage capacitor of the LCD includes the pixel electrode and the storage electrode overlapping each other, and the gate insulating layer sandwiched therebetween. Accordingly, the storage capacitor of the TFT array panel according to an embodiment of the present invention may have a higher electrical capacity than the known storage capacitor though the storage conductor 177 has the same area as the storage electrode of the known storage capacitor.

Meanwhile, the area of the conductors overlapping each other may be enlarged for increasing the electrical capacity, and then aperture ratio of the LCD may be decreased.

The storage capacitor of the TFT array panel according to an embodiment of the present invention includes a transparent electrode 192 and a storage conductor 177 overlapping each other along with the passivation layer 180 having a thin thickness D2 and sandwiched therebetween such that the storage capacitor has a higher electrical capacity than the known storage capacitor though the storage conductor 177 has the same area as the storage electrode of the known storage capacitor.

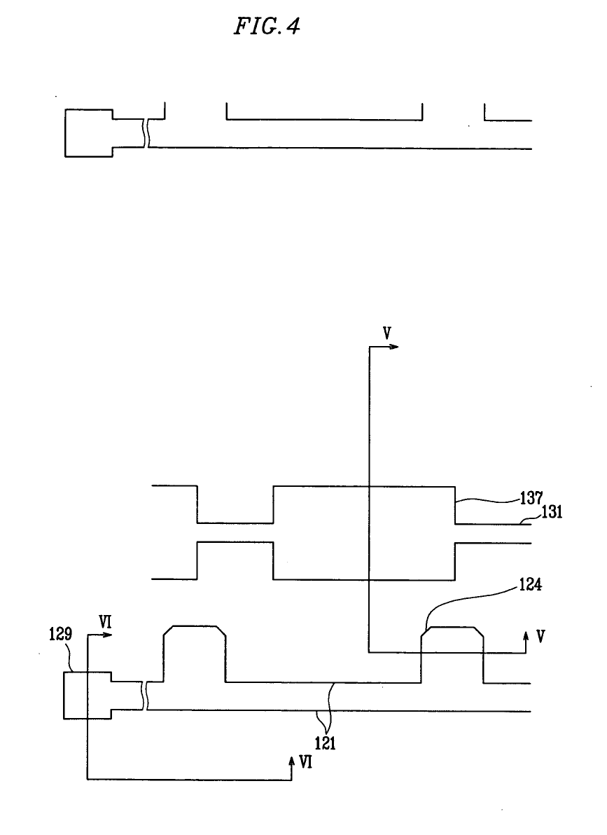

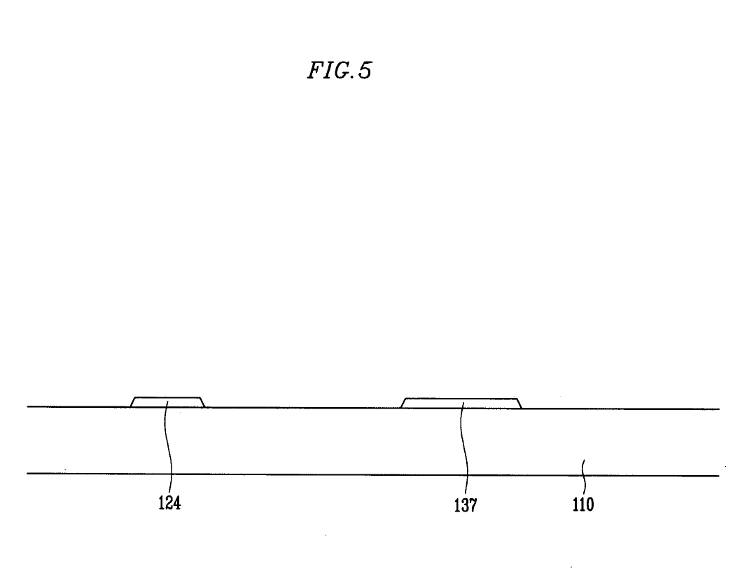

Now, a manufacturing method of the TFT array panel shown in FIG. 1 to FIG. 3 according to an embodiment of the present invention will be described in detail with reference to FIG. 4 to FIG. 18 as well as FIG. 1 to FIG. 3.

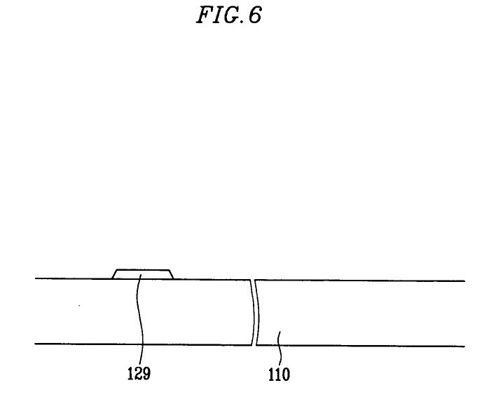

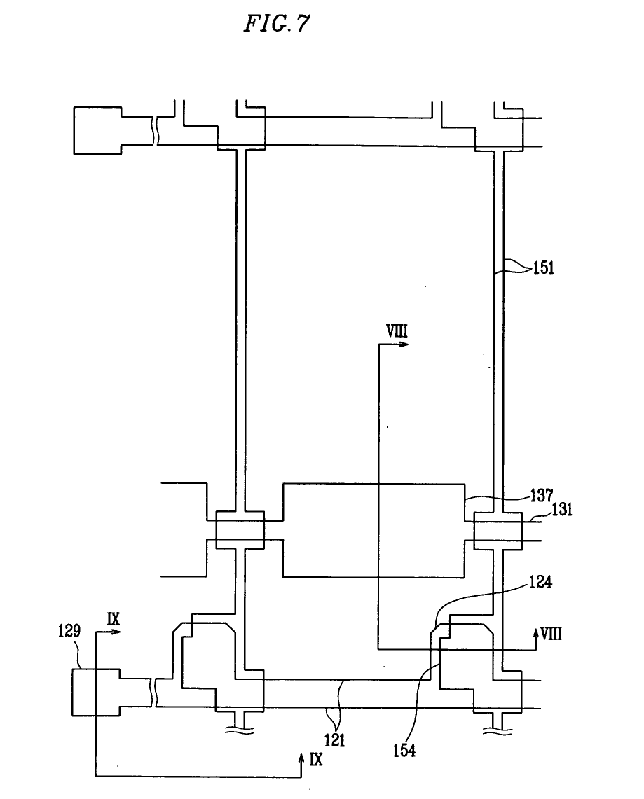

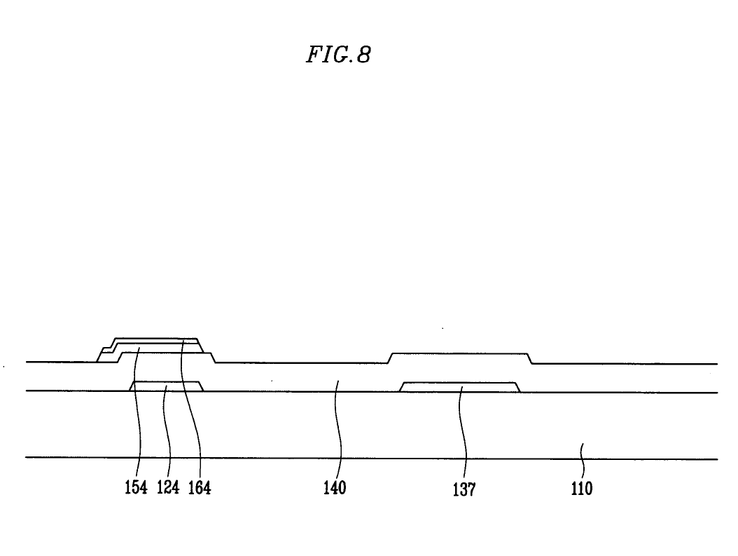

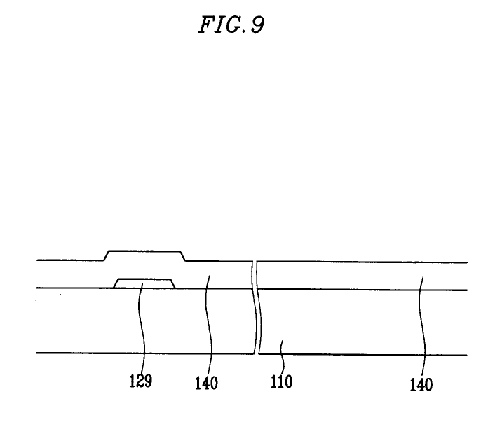

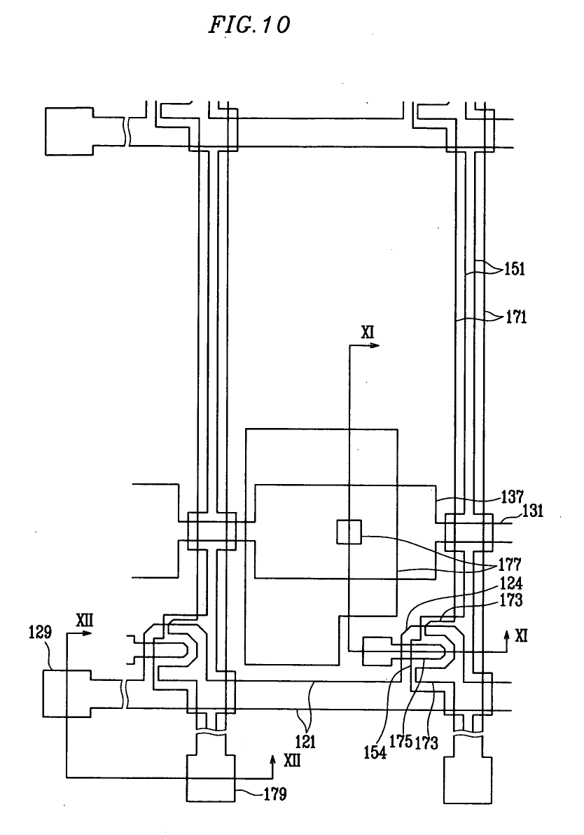

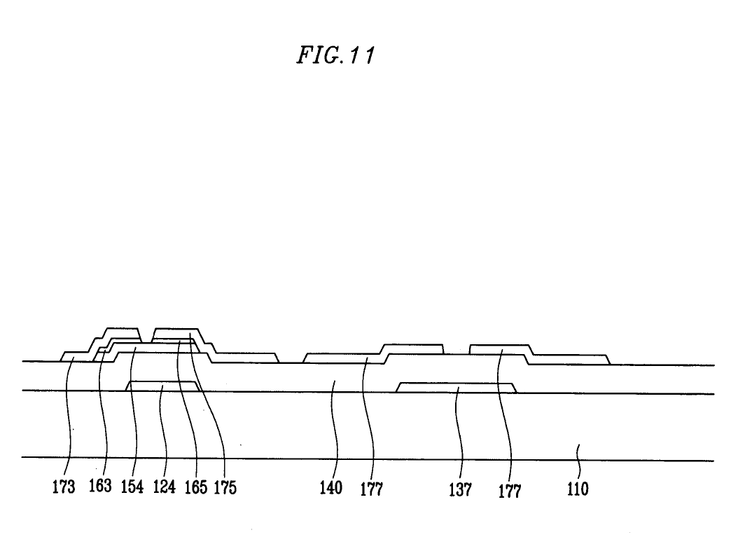

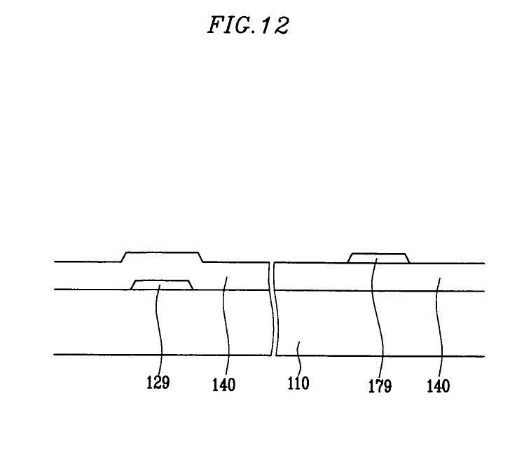

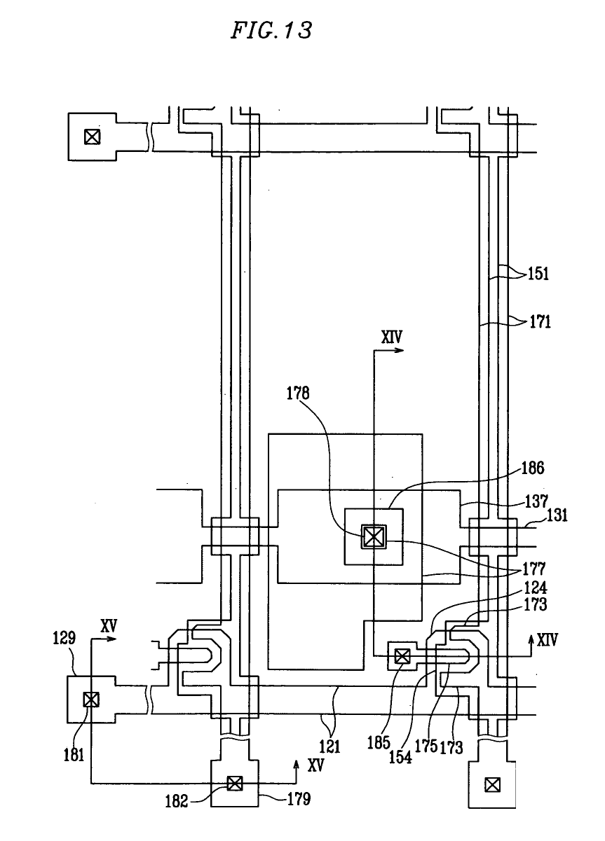

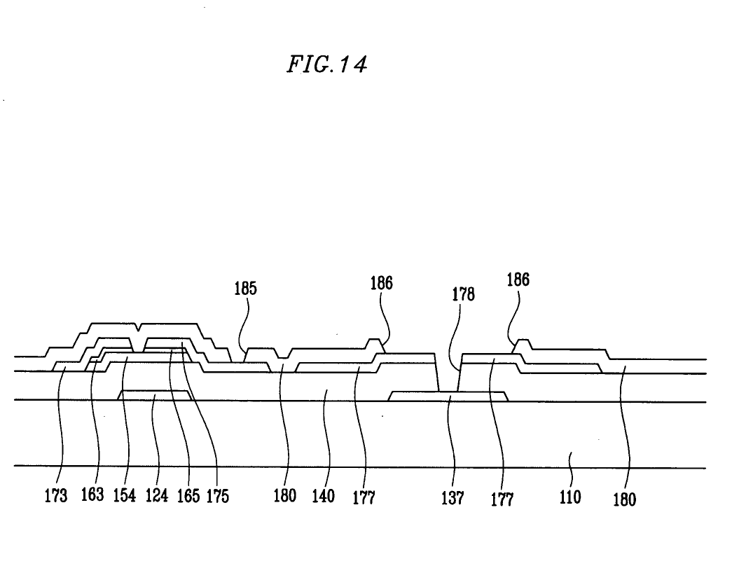

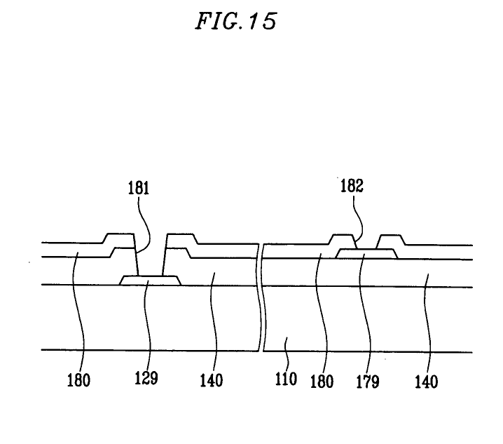

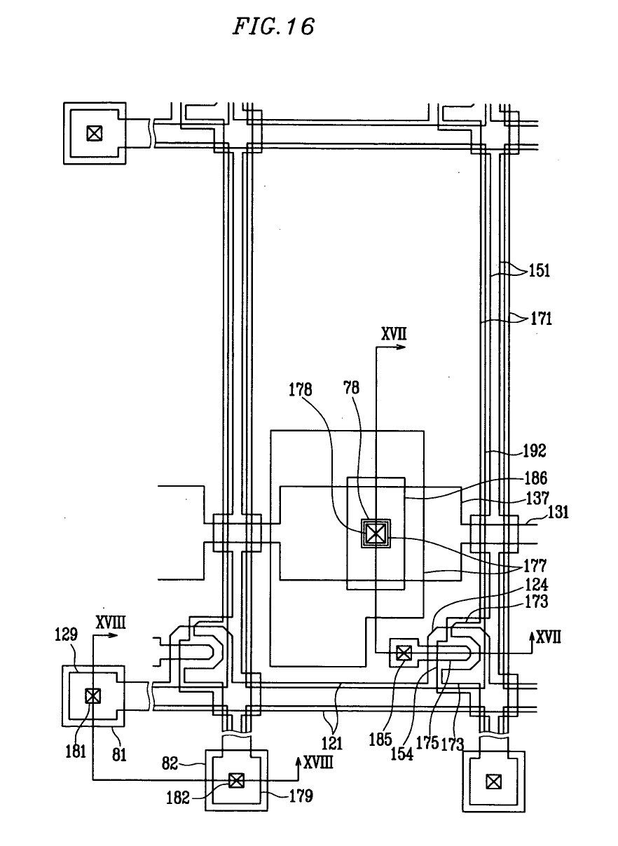

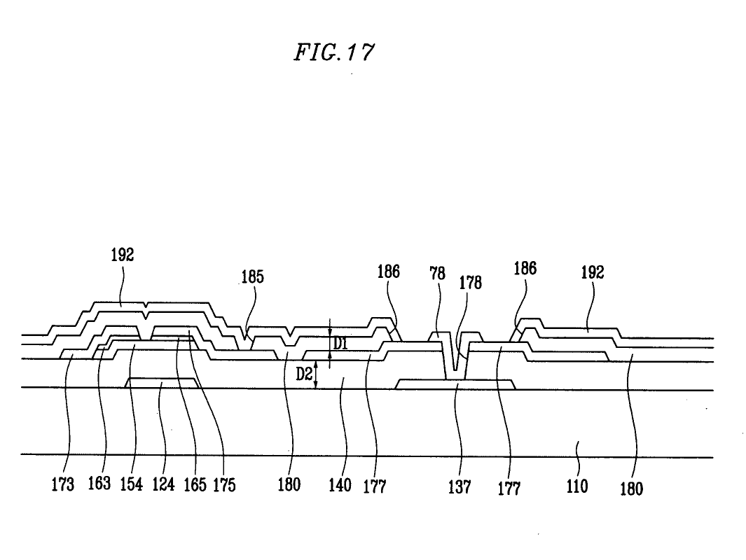

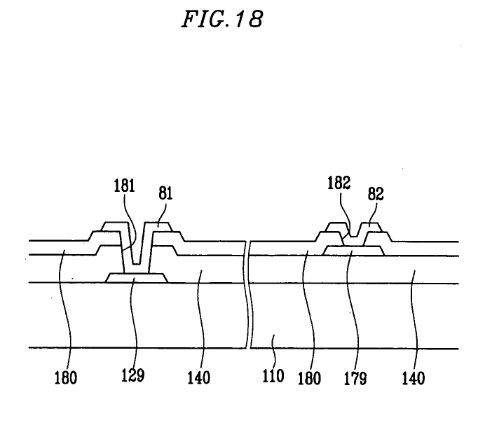

FIG. 4, FIG. 7, FIG. 10, FIG. 13, and FIG. 16 are layout views of the TFT array panel in intermediate steps of a manufacturing method thereof according to an embodiment of the present invention, FIG. 5 and FIG. 6 are sectional views of the TFT array panel shown in FIG. 4 taken along the lines V-V and VI-VI, FIG. 8 and FIG. 9 are sectional views of the TFT array panel shown in FIG. 7 taken along the lines VIII-VIII and IX-IX, FIG. 11 and FIG. 12 are sectional views of the TFT array panel shown in FIG. 10 taken along the lines XI-XI and XII-XII, FIG. 14 and FIG. 15 are sectional views of the TFT array panel shown in FIG. 13 taken along the lines XIV-XIV and XV-XV, and FIG. 17 and FIG. 18 are sectional views of the TFT array panel shown in FIG. 16 taken along the lines XVII-XVII and XVIII-XVIII.

Referring to FIG. 4 to FIG. 6, a metal layer is deposited on an insulating substrate 110 by sputtering, etc., and then the metal layer is patterned by photolithography and etching to form a plurality of gate lines 121 including gate electrodes 124 and end portions 129 and a plurality of storage electrode lines 131 including storage electrodes 137.

Next, a gate insulating layer 140 is deposited on the substrate 110 and then a plurality of (intrinsic) semiconductor stripes 151 including projections 154 and a plurality of extrinsic semiconductor stripes 161 including projections 164 are formed on the gate insulating layer 140 as shown in FIG. 7 to FIG. 9. Here, a gate insulating layer 140, an intrinsic a-Si layer, and an extrinsic a-Si layer are sequentially deposited on the substrate 110 having the gate lines 121 and the storage electrode lines 131, and then the extrinsic a-Si layer and the intrinsic a-Si layer are patterned by photolithography and etching.

Next, a metal layer is deposited on the extrinsic semiconductor stripes 161 and 164 and the gate insulating layer 140, and then the metal is patterned by photolithography and etching to form a plurality of data lines 171 including source electrodes 173 and end portions 179, a plurality of drain electrodes 175, and a plurality of storage conductors 177.

Thereafter, exposed portions of the extrinsic semiconductor stripes 164, which are not covered with the data lines 171 and the drain electrodes 175, are removed to complete a plurality of ohmic contact stripes 161 including projections 163 and a plurality of ohmic contact islands 165 and to expose portions of the intrinsic semiconductor stripes 151.

Next, a passivation layer 180 is deposited and patterned by photolithography (and etching) along with the gate insulating layer 140 to form a plurality of contact holes 181, 182, 185, and 178 exposing the end portions 129 of the gate lines 121, the end portions 179 of the data lines 171, the drain electrodes 175, and the storage electrodes 137, respectively, and a plurality of holes 186 exposing a portion of the storage conductors 177 as shown in FIG. 13 to FIG. 15. The thickness D1 of the passivation layer 180 is thinner than the thickness D2 of the gate insulating layer 140 by about half or more.

Referring to FIG. 16 to FIG. 18, a plurality of transparent electrodes 192, a plurality of contact assistants 81 and 82, and a plurality of connecting members 78 are formed on the substrate 110.

Finally, as shown in FIGS. 1 to 3, a plurality of organic insulators 187 are formed on a portion of the substrate 110, and then a plurality of reflective electrodes 194 are formed on the organic insulator 187. Here, each organic insulator 187 is disposed on a portion of each transparent electrode 192 and has an embossed surface.

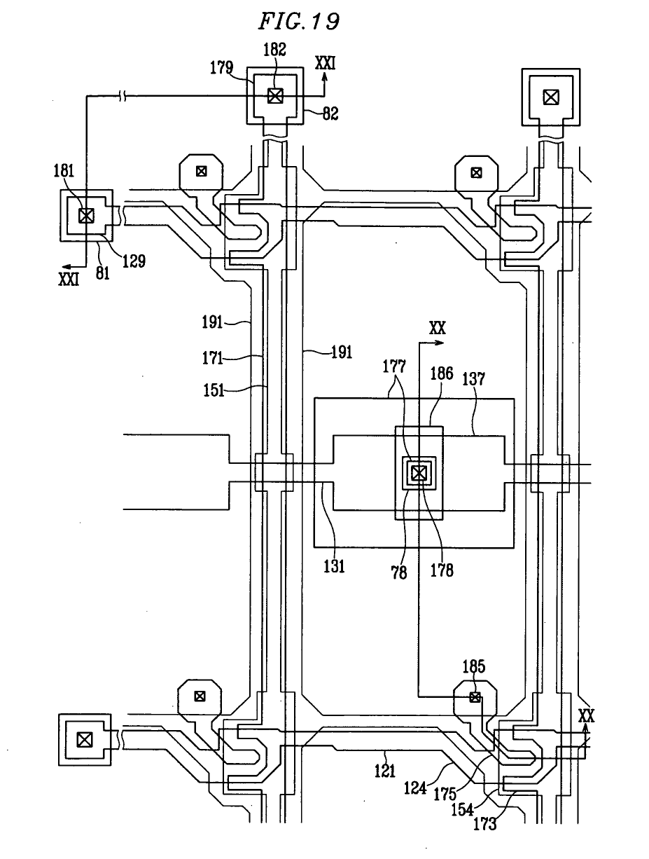

Now, a TFT array panel according to another embodiment of the present invention will be described in detail with reference to FIG. 19 to FIG. 21.

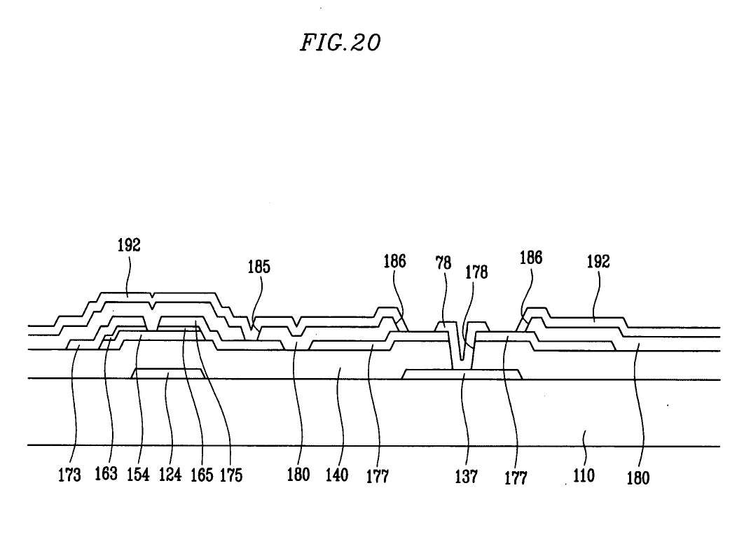

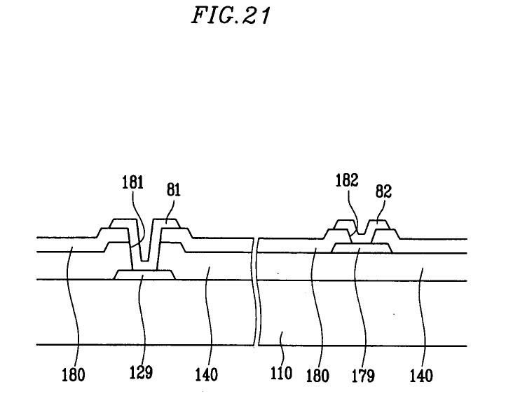

FIG. 19 is a layout view of a TFT array panel according to another embodiment of the present invention, and FIG. 20 and FIG. 21 are sectional views of the TFT array panel shown in FIG. 19 taken along the lines XX-XX and XXI-XXI.

As shown in FIG. 19 to FIG. 21, the layered structure of a TFT array panel according to the present embodiment is substantially the same as that shown in FIG. 1 to FIG. 3.

A plurality of gate lines 121 and a plurality of storage electrode lines 131 are formed on a substrate 110. Each gate line 121 includes a gate electrode 124 and an end portion 129, and each storage electrode line 131 includes a storage electrode 137. The gate insulating layer 140, a plurality of semiconductor stripes 151 including projections 154, and a plurality of ohmic contact stripes 161 including projections 163 and a plurality of ohmic contact islands 165 are sequentially formed on the gate lines 121 and the storage electrode lines 131.

A plurality of drain electrodes 175 and a plurality of data lines 171 including source electrodes 173 and end portions 179, and a plurality of storage conductors 177 are formed on the ohmic contacts 161 and 165 and the gate insulating layer 140, and a passivation layer 180 is formed thereon.

The passivation layer 180 and the gate insulating layer 140 have a plurality of contact holes 181 and 182, the passivation layer 180 has a plurality of contact holes 187 exposing the drain electrodes 175 and a plurality of holes 186 exposing a portion of the storage conductors 177, and the gate insulating layer 140 has a plurality of contact holes 178. A plurality of pixel electrodes 191, a plurality of contact assistants 81 and 82 are formed on the passivation layer 180, and a plurality of connecting members 78 are formed on the storage conductors 177 exposed through the holes 178.

However, unlike the TFT array panel shown in FIG. 1 to FIG. 3, the storage electrode lines 131, the storage electrodes 137, and the storage conductors 177 are disposed nearly equidistant between two adjacent gate lines 121. However, the storage electrode lines 131 and the storage conductors 177may have various shapes and arrangements. There are no organic insulators 187 and the reflective electrodes 194 in the TFT array panel according to the present embodiment.

In the TFT array panel according to the present embodiment, the pixel electrodes 191 overlap the storage conductors 177 electrically connected to the storage electrodes 137 to form a storage capacitors along with the passivation layer 180 sandwiched therebetween.

As described above, the TFT array panel according to the present embodiment includes the storage capacitors formed by the pixel electrodes 191 and the storage conductors 177 overlapping each other along with the passivation layer 180 sandwiched therebetween. The known storage capacitor of an LCD includes a pixel electrode and a storage electrode overlapping each other, and the gate insulating layer sandwiched therebetween. Accordingly, the storage capacitor of the TFT array panel according to present embodiment may have a higher electrical capacity than the known storage capacitor even though the storage conductor 177 has the same area as the storage electrode of the known storage capacitor.

Accordingly, the TFT array panel according to an embodiment of the present invention may include the storage capacitor having a higher electrical capacity than the known storage capacitor even though the storage conductor 177 has the same area as the storage electrode of the known storage capacitor such that the aperture ratio of the LCD including the TFT array panel may not be decreased.

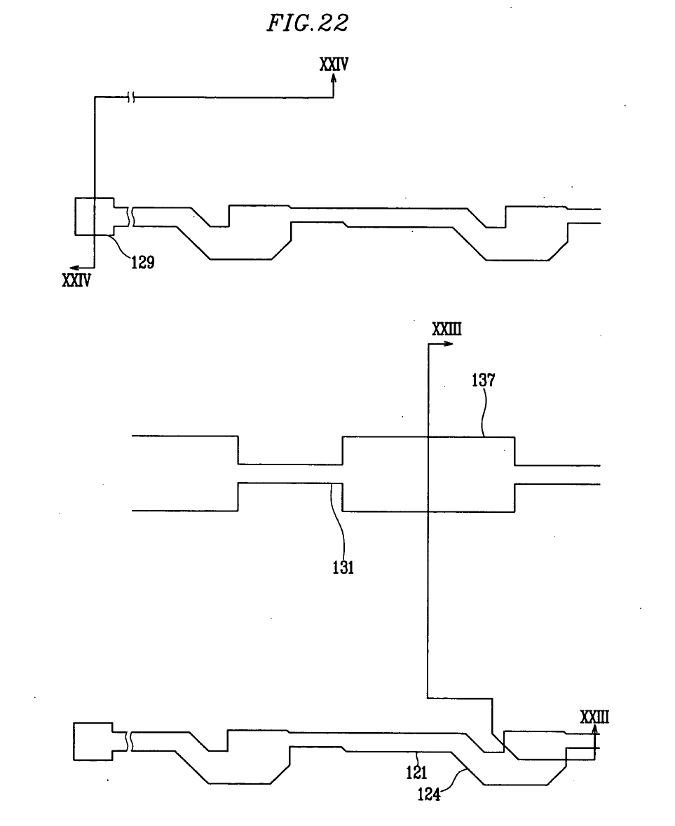

Now, a manufacturing method of the TFT array panel shown in FIG. 19 to FIG. 21 according to the present embodiment will be described in detail with reference to FIG. 22 to FIG. 33 along with FIG. 19 to FIG. 21.

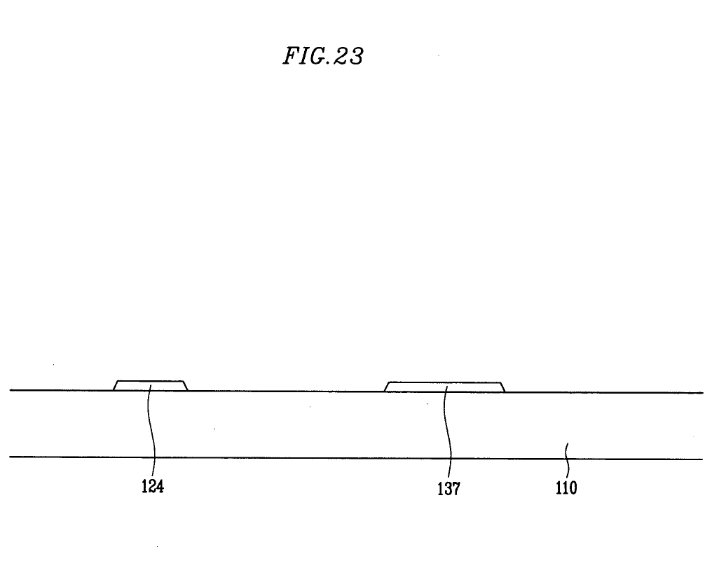

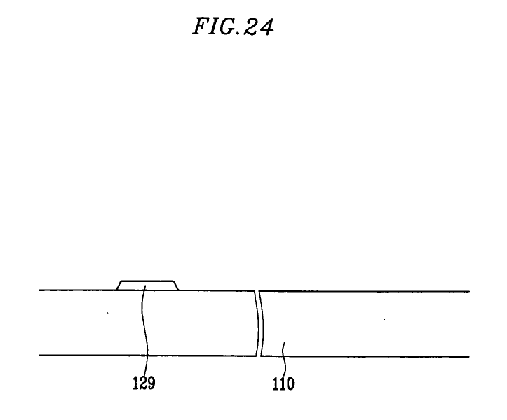

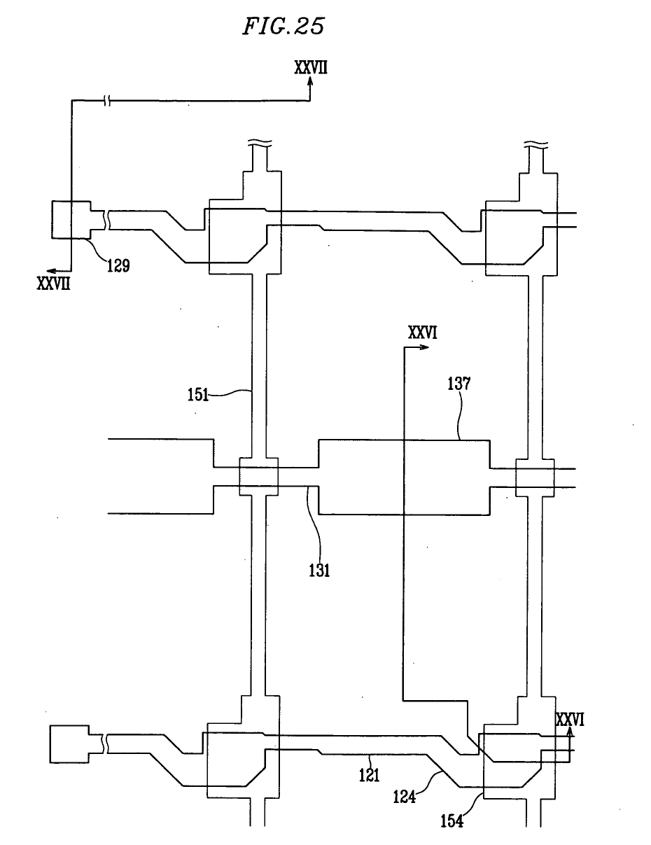

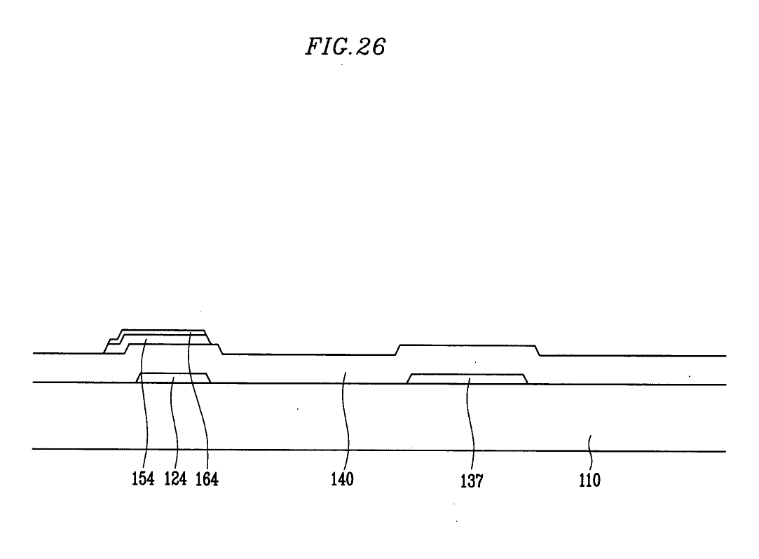

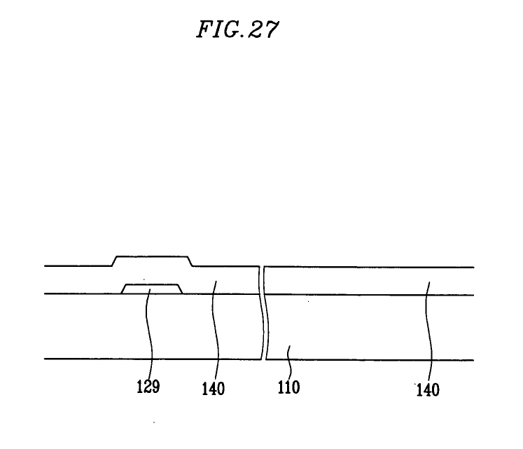

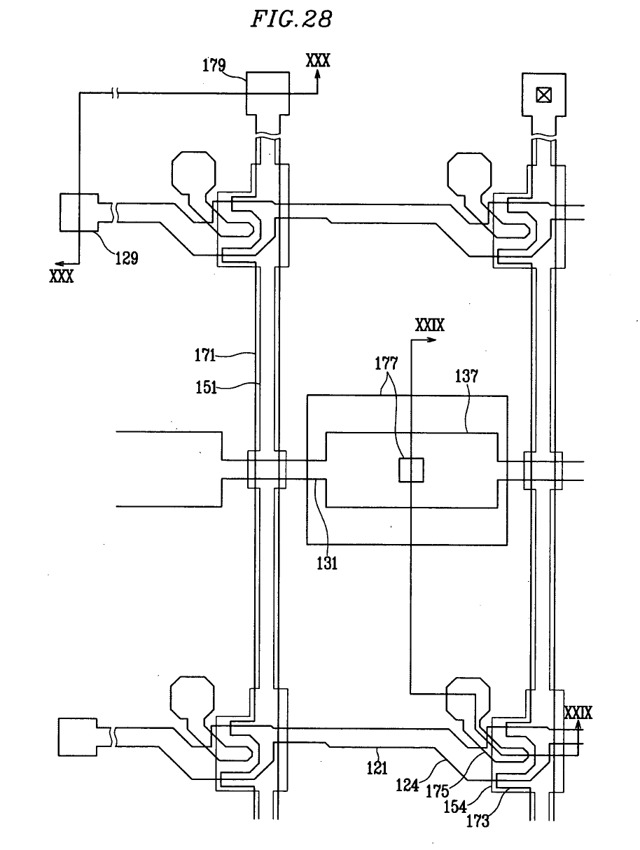

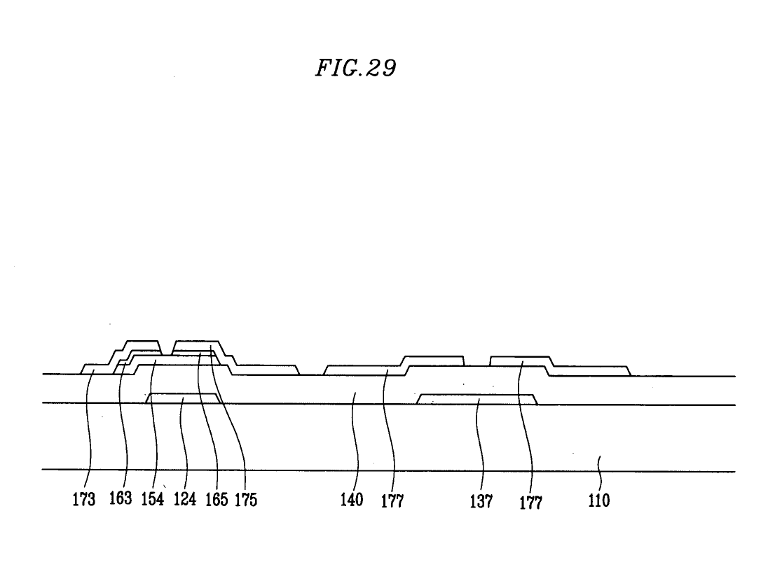

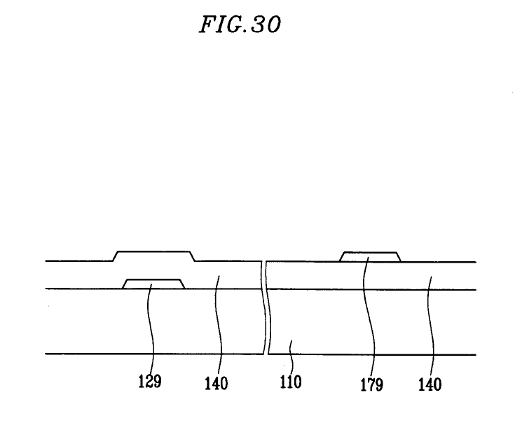

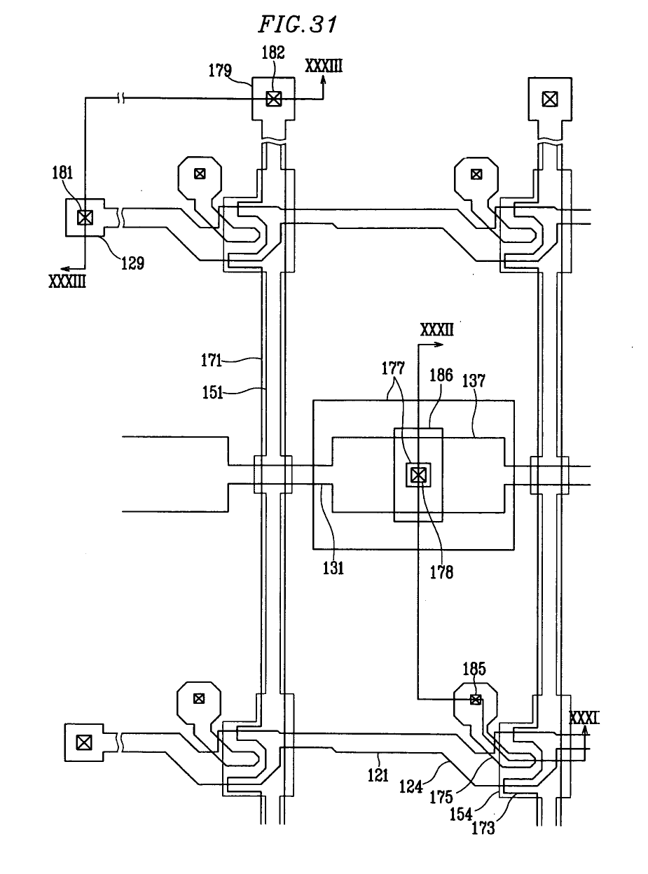

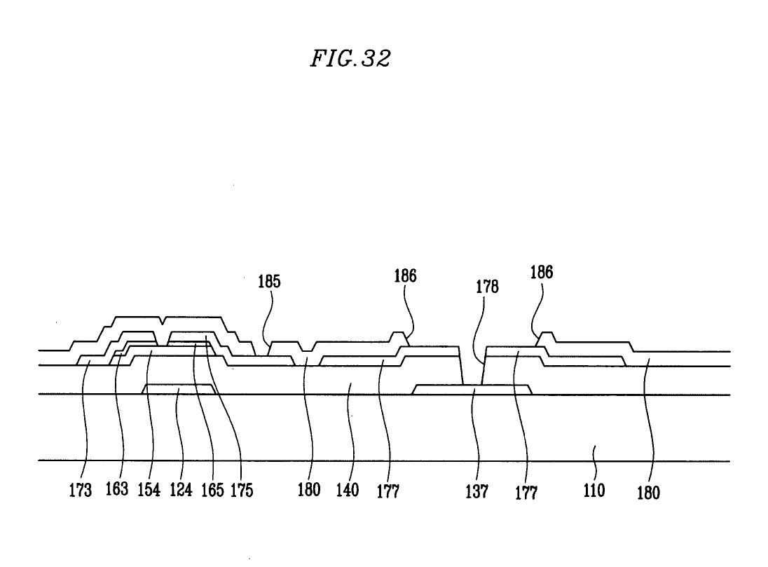

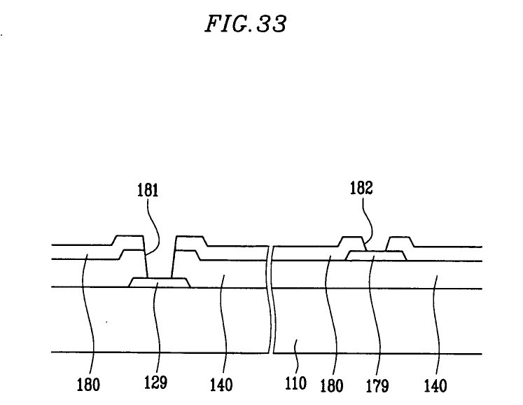

FIG. 22, FIG. 25, FIG. 28, and FIG. 31 are layout views of the TFT array panel in intermediate steps of a manufacturing method thereof according to another embodiment of the present invention, FIG. 23 and FIG. 24 are sectional views of the TFT array panel shown in FIG. 22 taken along the lines XXIII-XXIII and XXIV-XXIV, FIG. 26 and FIG. 27 are sectional views of the TFT array panel shown in FIG. 25 taken along the lines XXVI-XXVI and XXVII-XXVII, FIG. 29 and FIG. 30 are sectional views of the TFT array panel shown in FIG. 28 taken along the lines XXIX-XXIX and XXX-XXX, and FIG. 32 and FIG. 33 are sectional views of the TFT array panel shown in FIG. 31 taken along the lines XXXII-XXXII and XXXIII-XXXIII.

Referring to FIG. 22 to FIG. 24, a metal layer is deposited on an insulating substrate 110 by sputtering, etc., and then the metal layer is patterned by photolithography and etching to form a plurality of gate lines 121 including gate electrodes 124 and end portions 129 and a plurality of storage electrode lines 131 including storage electrodes 137.

A gate insulating layer 140 is deposited on the substrate 110, and then an intrinsic a-Si layer and an extrinsic a-Si layer are sequentially deposited on the substrate 110 and the extrinsic a-Si layer and the intrinsic a-Si layer are patterned by photolithography and etching to form a plurality of extrinsic semiconductor stripes 161 including projections 164 and a plurality of (intrinsic) semiconductor stripes 151 including projections 154 as shown in FIG. 25 to FIG. 27.

Referring to FIG. 28 to FIG. 30, a metal layer is deposited on the extrinsic semiconductor stripes 161 and 164 and the gate insulating layer 140, and then the metal is patterned by photolithography and etching to form a plurality of data lines 171 including source electrodes 173 and end portions 179, a plurality of drain electrodes 175, and a plurality of storage conductors 177. Thereafter, exposed portions of the extrinsic semiconductor stripes 164, which are not covered with the data lines 171 and the drain electrodes 175, are removed to complete a plurality of ohmic contact stripes 161 including projections 163 and a plurality of ohmic contact islands 165 and to expose portions of the intrinsic semiconductor stripes 151.

Next, a passivation layer 180 is deposited. Here, the thickness of the passivation layer 180 is thinner than that of the gate insulating layer 140 by about half or more.

The deposited passivation layer 180 is patterned by photolithography (and etching) along with the gate insulating layer 140 to form a plurality of contact holes 181, 182, 185, and 178 exposing the end portions 129 of the gate lines 121, the end portions 179 of the data lines 171, the drain electrodes 175, and the storage electrode 137, respectively, and a plurality of holes 186 exposing a portion of the storage conductors 177as shown in FIG. 31 to FIG. 33.

Finally, transparent conductor such as ITO or IZO is deposited on the substrate and patterned by photolithography and etching to form a plurality of pixel electrodes 192, a plurality of contact assistants 81 and 82, and a plurality of connecting members 78 as shown in FIG. 19 to FIG. 21.

Now, a TFT array panel according to another embodiment of the present invention will be described in detail with reference to FIG. 34 to FIG. 36.

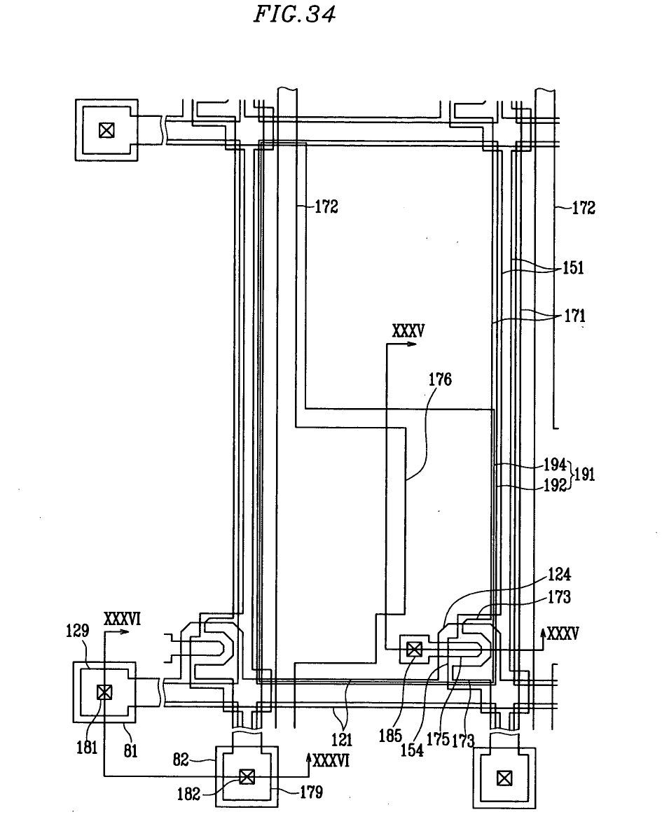

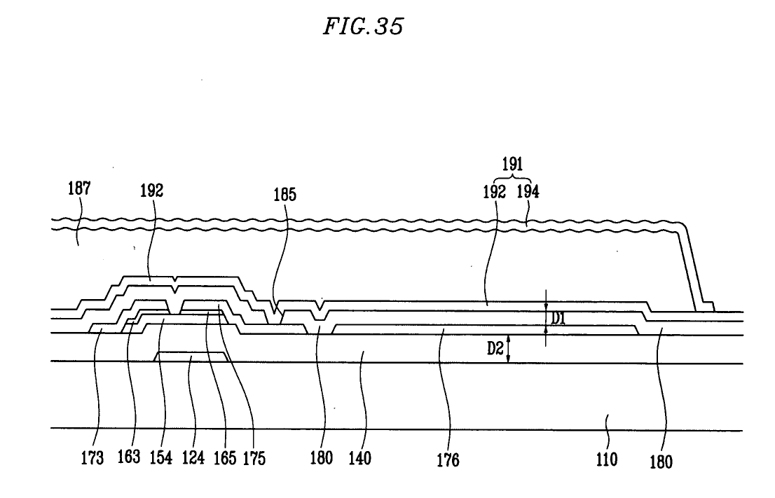

FIG. 34 a layout view of a TFT array panel according to another embodiment of the present invention and FIG. 35 and FIG. 36 are sectional views of the TFT array panel shown in FIG. 34 taken along the lines XXXV-XXXV and XXXVI-XXXVI.

A plurality of gate lines 121 are formed on an insulation substrate 110. Each gate line 121 includes a gate electrode 124 and an end portion 129.

A gate insulating layer 140 is formed on the gate lines 121 and the substrate 110.

A plurality of semiconductor stripes 151 are formed on the insulating layer 140. Each of the semiconductor stripes 151 extends substantially in the longitudinal direction and includes a projection 154 branched out toward the gate electrode 124. The semiconductor stripes 151 become wide near the gate lines 121 such that the semiconductor stripes 151 cover large areas of the gate lines 121.

A plurality of ohmic contact stripes and islands 161 and 165 are formed on the semiconductor stripes 151. Each of the ohmic contact stripes 161 includes a plurality of projections 163, and the projections 163 and the ohmic contact islands 165 are located in pairs on the projections 154 of the semiconductor stripes 151.

A plurality of data lines 171, a plurality of drain electrodes 175, and a plurality of storage electrode lines 172 are formed on the ohmic contacts 161, 163, and 165 and the gate insulating layer 140. The data lines 171 transmit data signals and extend substantially in the longitudinal direction to intersect the gate lines 121. Each data line 171 includes a source electrode 173 projecting toward the gate electrode 124, and an end portion 179 having a large area for contact with another layer or an external driving circuit. The drain electrodes 175 are separated from the data lines 171, and are disposed opposite the source electrodes 173 with respect to the gate electrodes 124. Each of the drain electrodes 175 includes a wide end portion and a narrow end portion. The wide end portion is connected to a transparent electrode 192 through a contact hole 185 and the narrow end portion is partly enclosed by a source electrode 173.

A gate electrode 124, a source electrode 173, and a drain electrode 175 along with a projection 154 of a semiconductor stripe 151 form a TFT having a channel formed in the projection 154 disposed between the source electrode 173 and the drain electrode 175.

Each of the storage electrode lines 172 includes a storage electrode 176 expanding upward and downward. The storage electrode lines 172 are supplied with a predetermined voltage and extend substantially parallel to the date lines 171. The storage electrode lines 172 may be made of the same material as the data lines 171 simultaneously, separated from the data lines 171 and drain electrodes 175, and mostly disposed in the region corresponding to reflective electrodes 194. The end portions of the storage electrode lines 172 are supplied with the storage voltage from the external storage driving member.

A passivation layer 180 is formed on the data lines 171, the drain electrodes 175, the storage electrode lines 172, and the exposed portions of the semiconductor stripes 151. The passivation layer 180 may be made of an inorganic insulator such as silicon nitride and silicon oxide. The passivation layer 180 may have a thickness thinner than that of the gate insulating layer 104 by about half or more. The passivation layer 180 has a plurality of contact holes 182 and 185 exposing the end portions 179 of the data lines 171 and the drain electrodes 175, respectively. The passivation layer 180 and the gate insulating layer 140 have a plurality of contact holes 181 exposing the end portions 129 of the gate lines 121.

A plurality of transparent electrodes 192 and a plurality of contact assistants 81 and 82 are formed on the passivation layer 180.

A plurality of organic insulators 187 having photosensitivity and a good planarization characteristic are formed on the transparent electrodes 192 and the passivation layer 180. A plurality of reflective electrodes 194 are formed on the organic insulators 187. The organic insulator 187 has an embossed surface. Each reflective electrode 194 is curved along the embossed surface of the organic insulator 187 to have protrusion patterns and depression patterns. The protrusion patterns and depression patterns of the reflective electrode 194 enhance reflective efficiency. Each organic insulator 187 may be disposed on a portion of each transparent electrode 192. The organic insulators 187 are eliminated in the regions of the end portions 129 of the gate lines 121, and the end portions 179 of the data lines 171.

The pixel electrode 191 includes the transparent electrode 192 and the reflective electrode 194 disposed on the organic insulator 187 and curved along the embossed surface of the organic insulator 187.

The transflective LCD liquid crystal display includes a transmissive area TA and a reflective area RA defined by the transparent electrode 192s and the reflective electrode 194s, respectively. In detail, areas disposed under and over exposed portions of the transparent electrodes 192 from the organic insulator 187 are transmissive regions TA, and areas disposed under and over reflective electrodes 194 are reflective regions RA.

The reflective electrodes 194 are physically and electrically connected to the transparent electrodes 192 at the edge of the transmissive regions TA and the reflective regions RA.

Each storage electrode 176 is disposed in the reflective region RA.

The transparent electrodes 192 and the reflective electrodes 194 connected thereto are physically and electrically connected to the drain electrodes 175 through the contact holes 185 such that the pixel electrodes 191 including the transparent electrodes 192 and the reflective electrodes 194 receive data voltages from the drain electrodes 175. The pixel electrodes 191 supplied with the data voltages generate electric fields in cooperation with a common electrode (not shown) of an opposing display panel (not shown) supplied with a common voltage, which determine the orientations of liquid crystal molecules (not shown) of a liquid crystal layer (not shown) disposed between the two electrodes. A pixel electrode 191 and the common electrode form a capacitor referred to as a “liquid crystal capacitor,” which stores applied voltages after the TFT turns off.

The transparent electrodes 192 overlap the storage electrode lines 172 including the storage electrodes 176 and are separated by the passivation layer 180 sandwiched therebetween.

The transparent electrodes 192 and the storage electrode lines 172 including the storage electrodes 176 form storage capacitors along with the passivation layer 180 sandwiched therebetween.

As described above, the TFT array panel according to the present embodiment includes the storage capacitors formed by transparent electrodes 192 and the storage electrode lines 172 including the storage electrodes 176 overlapping each other along with the passivation layer 180 sandwiched therebetween.

The gate insulating layer 140 may have the substantially same dielectric constant as the passivation layer 180, and the thickness D1 of the gate insulating layer 140 may be thicker than the thickness D2 of the passivation layer 180 by about two times.

Accordingly, if the area of the conductors overlapping each other is equal, the capacitor including two conductors and the passivation layer 180 sandwiched therebetween may have a higher electrical capacity C than the capacitor including two conductors and the gate insulating layer 140 sandwiched therebetween by two times or more.

As described above, the TFT array panel according to the present embodiment includes the storage capacitors formed by transparent electrodes 192 and the storage electrode lines 172 including the storage electrodes 176 overlapping each other along with the passivation layer 180 sandwiched therebetween.

The known storage capacitor of an LCD includes a pixel electrode and a storage electrode overlapping each other, and a gate insulating layer sandwiched therebetween. Accordingly, the storage capacitor of the TFT array panel according to the present embodiment may have a higher electrical capacity than the known storage capacitor even though the storage electrode 176 has the same area as the storage electrode of the known storage capacitor.

Accordingly, the TFT array panel according to an embodiment of the present invention may include the storage capacitor having a higher electrical capacity than the conventional storage capacitor even though the storage electrode 176 has the same area as the storage electrode of a conventional storage capacitor. In other words the present invention including the TFT array panel does not decrease the aperture ratio of the LCD In the TFT array panel according to the present embodiment, the storage electrode 176 is supplied with the storage voltage from the external storage driving member directly, as opposed to the storage conductor 177 of the TFT array panel according to the previous embodiment supplied with the storage voltage through the contact hole 178 from the storage electrode 137 indirectly. Accordingly, in the TFT array panel according to the present embodiment, the area corresponding to the contact hole 178 may be used in the storage conductor such that total area of the storage electrode may be reduced even though the storage capacitor has the same electrical capacity as the previous storage capacitor.

A manufacturing method of the TFT array panel according to the present embodiment is substantially similar to that of the TFT array panel according to the previous embodiment.

Referring to FIG. 34 to FIG. 37, a plurality of gate lines 121 including gate electrodes 124 and end portions 129 are formed on a substrate 110.

Next, a gate insulating layer 140 is deposited on the substrate 110, and then a plurality of (intrinsic) semiconductor stripes 151 including projections 154 and a plurality of extrinsic semiconductor stripes 161 including projections 164 are formed on the gate insulating layer 140. A plurality of data lines 171 including source electrodes 173 and end portions 179, a plurality of drain electrodes 175, and a plurality of storage electrode lines 172 including storage electrodes 176 are formed on the extrinsic semiconductor stripes 161 and 164 and the gate insulating layer 140, and thereafter, exposed portions of the extrinsic semiconductor stripes 164, which are not covered with the data lines 171 and the drain electrodes 175, are removed to complete a plurality of ohmic contact stripes 161 including projections 163 and a plurality of ohmic contact islands 165 and to expose portions of the intrinsic semiconductor stripes 151.

Next, a passivation layer 180 is deposited. Here, the thickness of the passivation layer 180 may be thinner than that of the gate insulating layer 140 by about half or more. The deposited passivation layer 180 is patterned by photolithography (and etching) along with the gate insulating layer 140 to form a plurality of contact holes 181, 182, and 185 exposing the end portions 129 of the gate lines 121, the end portions 179 of the data lines 171, and the drain electrodes 175, respectively.

Next, a plurality of pixel electrodes 192, and a plurality of contact assistants 81 and 82 are formed on the passivation layer 180.

Finally, a plurality of organic insulators 187 are formed on a portion of the substrate, and then a plurality of reflective electrodes 194 are formed on the organic insulator 187. Here, the organic insulator 187 has an embossed surface. Each reflective electrode 194 is curved along the embossed surface of the organic insulator 187 to have protrusion patterns and depression patterns.

The reflective electrodes 194 are physically and electrically connected to the transparent electrodes 192 at the edge of the transmissive region and the reflective regions.

However, unlike the manufacturing method according to the previous embodiments, the storage electrode lines 172 are formed along with the data lines 171, extend substantially parallel to the date lines 171, and are supplied with the storage voltage from the external storage driving member directly without the contact hole shown in the previous embodiments.

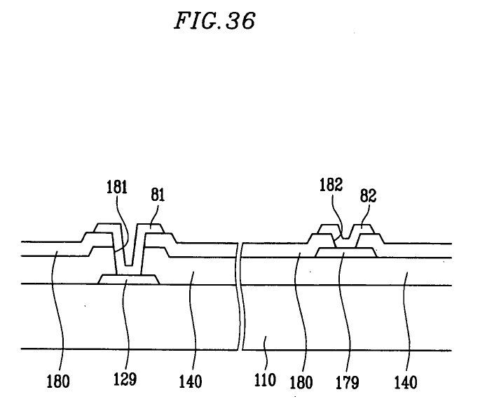

Next, a TFT array panel according to another embodiment of the present invention will be described in detail with reference to FIG. 37 to FIG. 39.

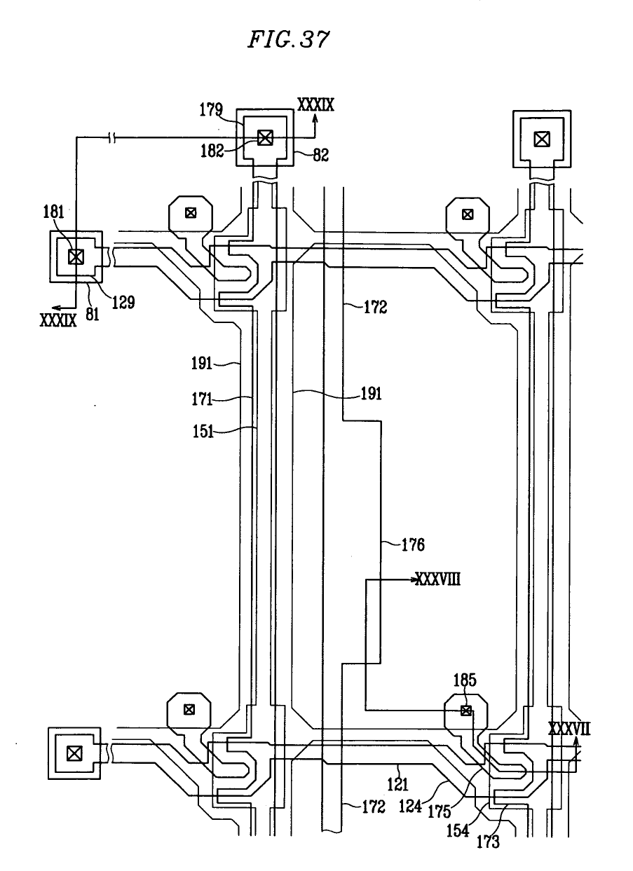

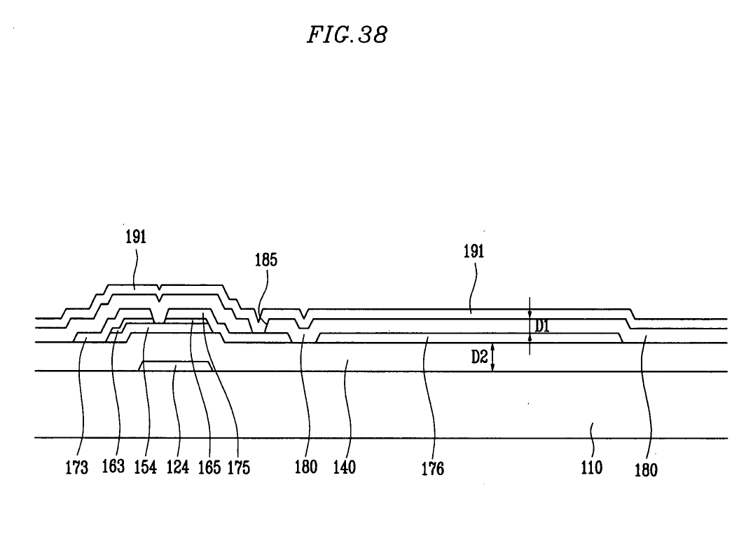

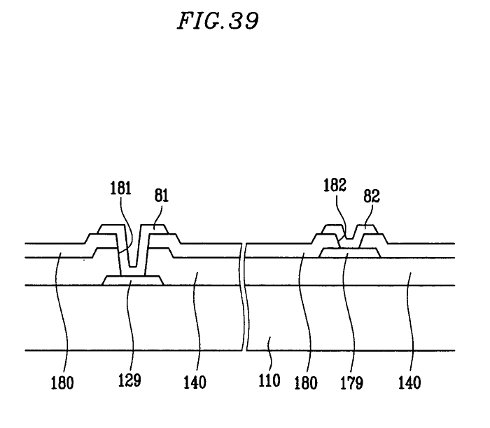

FIG. 37 a layout view of a TFT array panel according to another embodiment of the present invention, and FIG. 38 and FIG. 39 are sectional views of the TFT array panel shown in FIG. 37 taken along the lines XXXVIII-XXVIII and XXXIX-XXXIX.

As shown in FIG. 37 to FIG. 39, a layered structure of a TFT array panel according to the present embodiment is the substantially same as that shown in FIG. 34 to FIG. 36.

A plurality of gate lines 121 are formed on an insulation substrate 110.

A gate insulating layer 140, a plurality of semiconductor stripes 151 including a plurality of projections 154 branched out toward the gate electrodes 124, a plurality of ohmic contact stripes 161 including a plurality of projections 163, and a plurality of ohmic contact islands 165 are formed on the substrate 110.

A plurality of data lines 171 transmitting data signals and extending substantially in the longitudinal direction to intersect the gate lines 121, a plurality of drain electrodes 175, and a plurality of storage electrode lines 172 are formed on the ohmic contacts 161, 163, and 165 and the gate insulating layer 140, and a passivation layer 180 is formed thereon. The passivation layer 180 may have a thickness thinner than that of the gate insulating layer 104 by about half or more.

The passivation layer 180 and the gate insulating layer 140 have a plurality of contact holes 181,182, and 185.

A plurality of pixel electrodes 191 and a plurality of contact assistants 81 and 82 are formed on the passivation layer 180.

However, unlike the TFT array panel shown in FIG. 34 to FIG. 36, there are no organic insulators 187 and the reflective electrodes 194 in the TFT array panel according to the present embodiment.

The TFT array panel according to the present embodiment includes storage capacitors formed by pixel electrodes 191 and the storage conductors 177 overlapping each other along with the passivation layer 180 sandwiched therebetween.

Accordingly, the TFT array panel according to an embodiment of the present invention may include a storage capacitor having a higher electrical capacity than the known storage capacitor even though the storage conductor 177 has the same area as the storage electrode of the known storage capacitor such that the aperture ratio of the LCD including the TFT array panel may not be decreased.

In the TFT array panel according to the present embodiment, the storage electrodes 176 are supplied with the storage voltage from the external storage driving member directly, as opposed to the storage conductors 177 of the TFT array panel according to the previous embodiment supplied with the storage voltage through the contact holes 178 from the storage electrodes 137 indirectly.

Accordingly, in the TFT array panel according to the present embodiment, the area corresponding to the contact hole 178 may be used in the storage conductor such that total area of the storage electrode may be reduced even though the storage capacitor has the same electrical capacity as the previous storage capacitor.

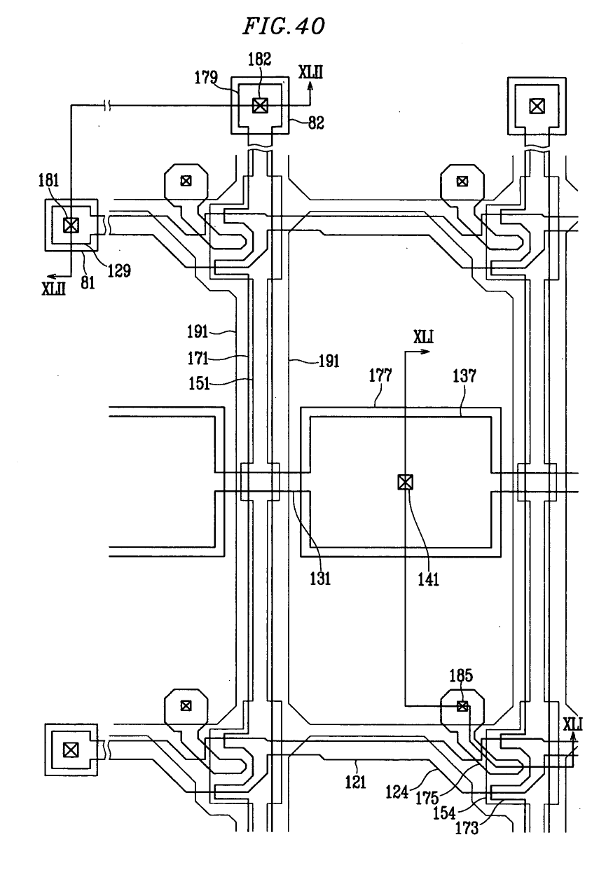

Now, a TFT array panel according to another embodiment of the present invention will be described in detail with reference FIG. 40 to FIG. 42.

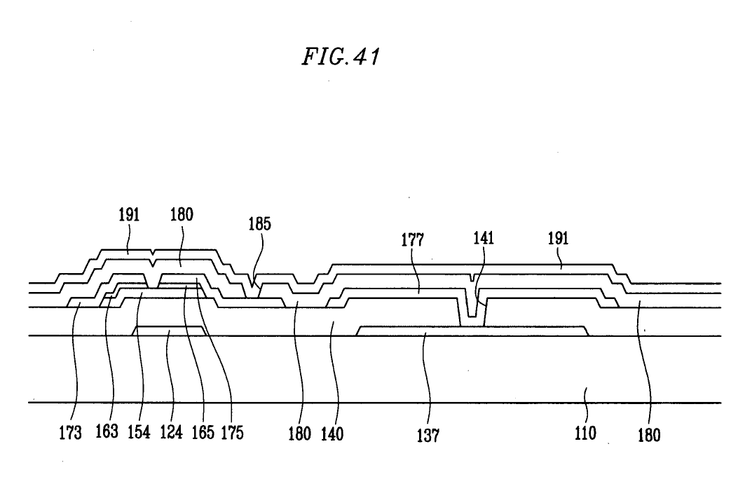

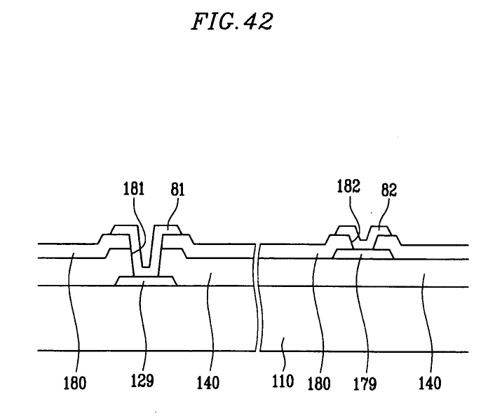

FIG. 40 a layout view of a TFT array panel according to another embodiment of the present invention, and FIG. 41 and FIG. 42 are sectional views of the TFT array panel shown in FIG. 40 taken along the lines XLI-XLI and XLII-XLII.

As shown in FIG. 40 to FIG. 42, a layered structure of a TFT array panel according to the present embodiment is substantially similar to FIG. 19 to FIG. 21.

A plurality of gate lines 121 and a plurality of storage electrode lines 131 are formed on a substrate 110. Each gate line 121 includes a gate electrode 124 and an end portion 129, and each storage electrode line 131 includes a storage electrode 137.

A gate insulating layer 140, a plurality of semiconductor stripes 151 including projections 154, and a plurality of ohmic contact stripes 161 including projections 163 and a plurality of ohmic contact islands 165 are sequentially formed on the gate lines 121 and the storage electrode lines 131.

A plurality of drain electrodes 175, a plurality of data lines 171 including source electrodes 173 and end portions 179, and a plurality of storage conductors 177 are formed on the ohmic contacts 161 and 165 and the gate insulating layer 140, and a passivation layer 180 is formed thereon.

The passivation layer 180 and the gate insulating layer 140 have a plurality of contact holes 181, 182, and 185, and the gate insulating layer 140 has a plurality of contact holes 141 exposing the storage electrodes.

A plurality of pixel electrodes 191 and a plurality of contact assistants 81 and 82 are formed on the passivation layer 180.

However, unlike the TFT array panel shown in FIG. 19 to FIG. 21, each storage conductor 177 has a rectangular shape without a hole and covering the whole storage electrode 137, and the storage conductor 177 is physically and electrically connected to the storage electrode 137 through the contact hole 141 of the gate insulating layer 140 directly without the connecting member.

Accordingly, the total area of the storage conductor included in the storage capacitor is increased even though the aperture ratio of the LCD including the TFT array panel is not decreased.

As described above, the TFT array panel according to the present embodiment includes the storage capacitors formed by pixel electrodes 191 and the storage conductors 177 overlapping each other along with the passivation layer 180 sandwiched therebetween.

The conventional LCD storage capacitor includes a pixel electrode and a storage electrode overlapping each other with the gate insulating layer sandwiched therebetween. Accordingly, the storage capacitor of the TFT array panel according to the present embodiment may have a higher electrical capacity than the conventional storage capacitor even though the storage conductor 177 has the same area as the storage electrode of the conventional storage capacitor.

Accordingly, the TFT array panel according to an embodiment of the present invention may include the storage capacitor having a higher electrical capacity than the conventional storage capacitor even though the storage conductor 177 has the same area as the storage electrode of the known storage capacitor such that the aperture ratio of the LCD including the TFT array panel may not be decreased.

The storage conductor 177 covers the whole storage electrode 137 such that the area of the storage conductor 177 is increased to enhance the capacity of the storage capacitor even though the aperture ratio of the LCD including the TFT array panel may be decreased.

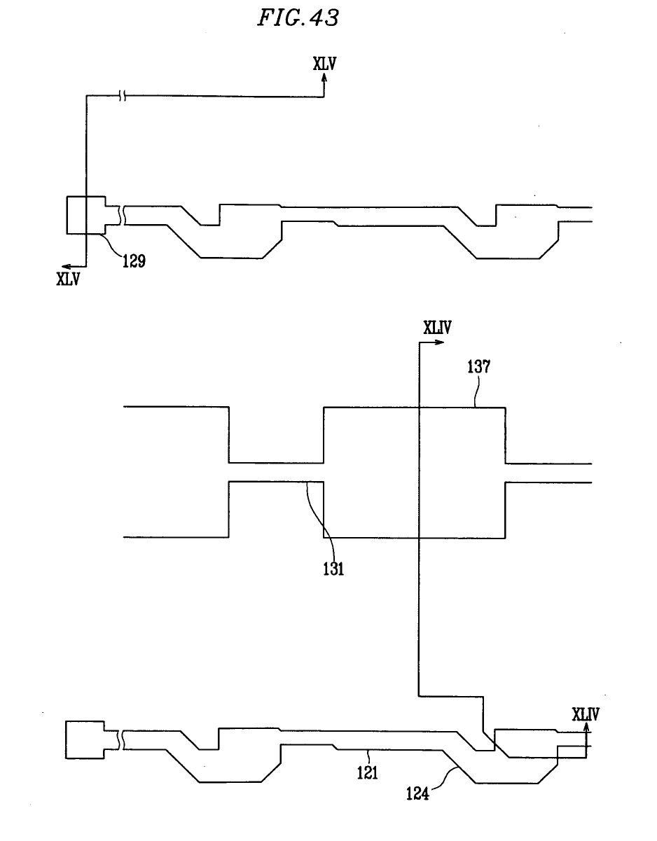

Now, a manufacturing method of the TFT array panel shown in FIG. 40 to FIG. 42 according to the present embodiment will be described in detail with reference to FIG. 43 to FIG. 54 along with FIG. 40 to FIG. 42.

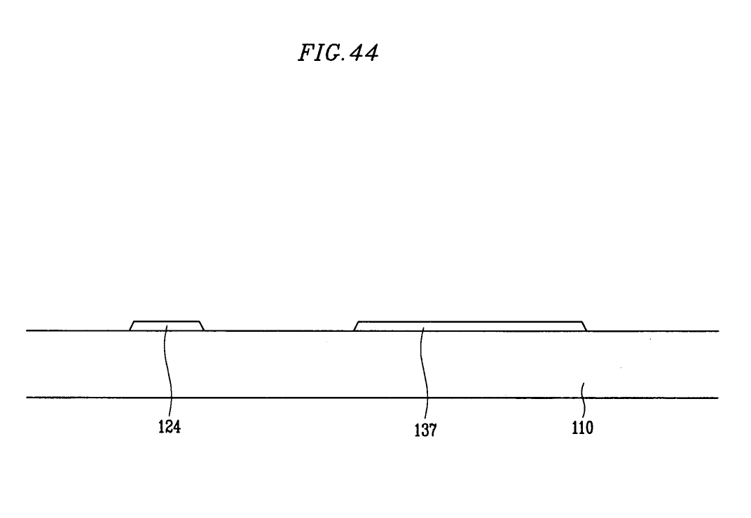

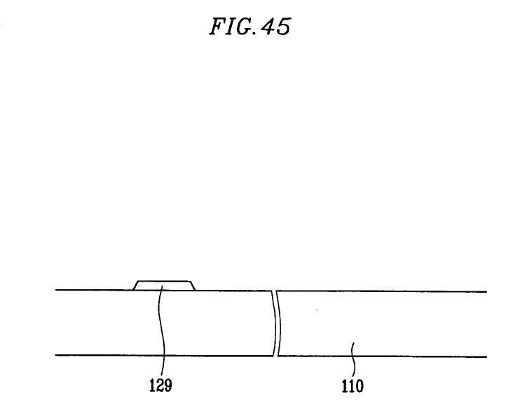

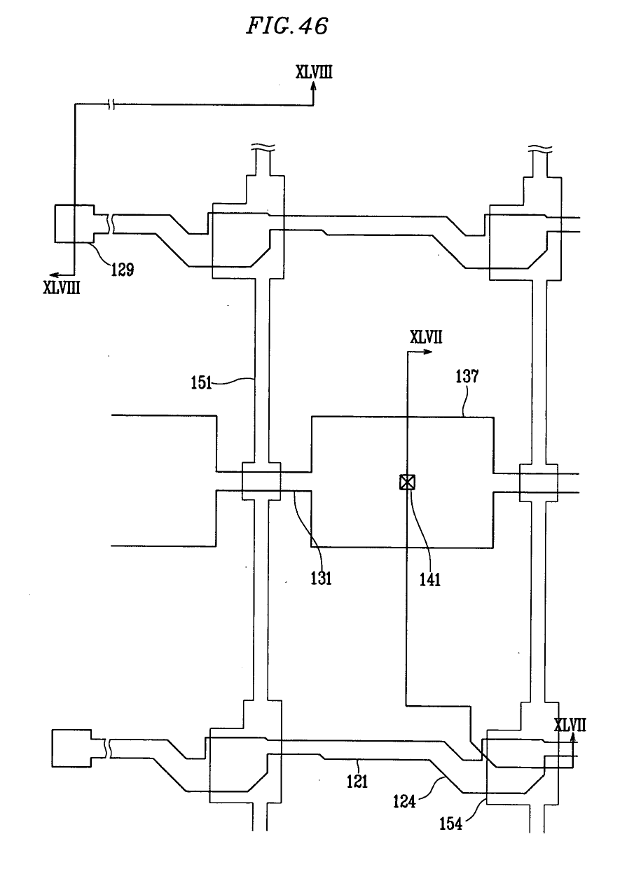

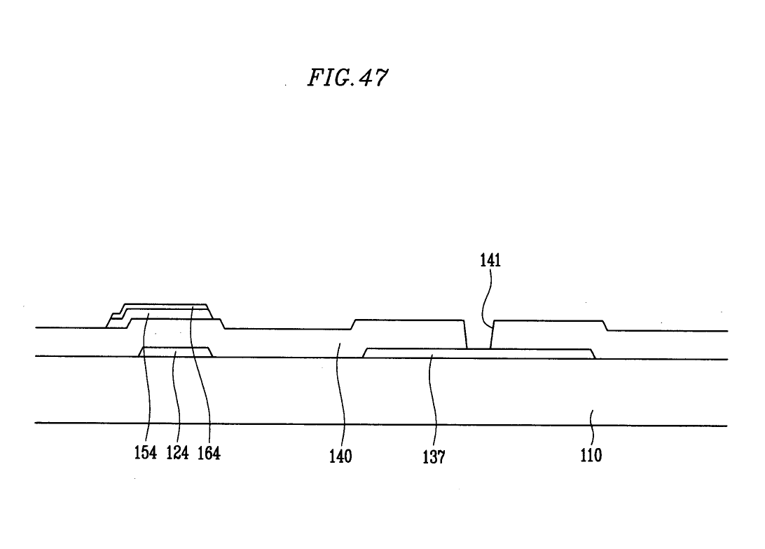

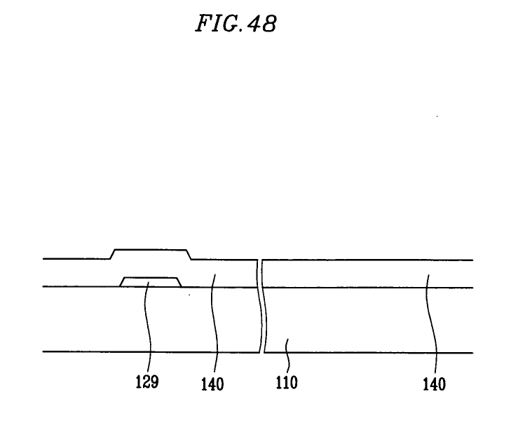

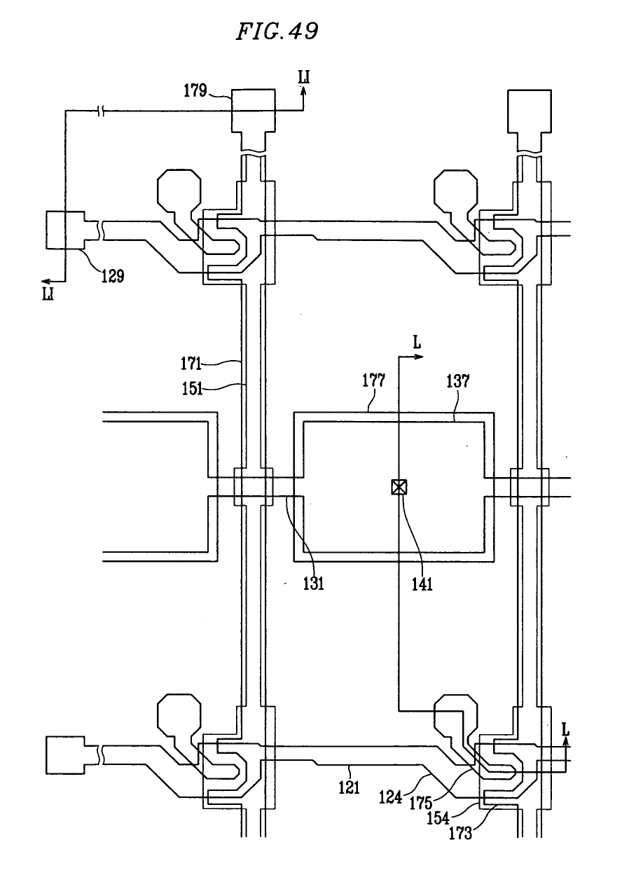

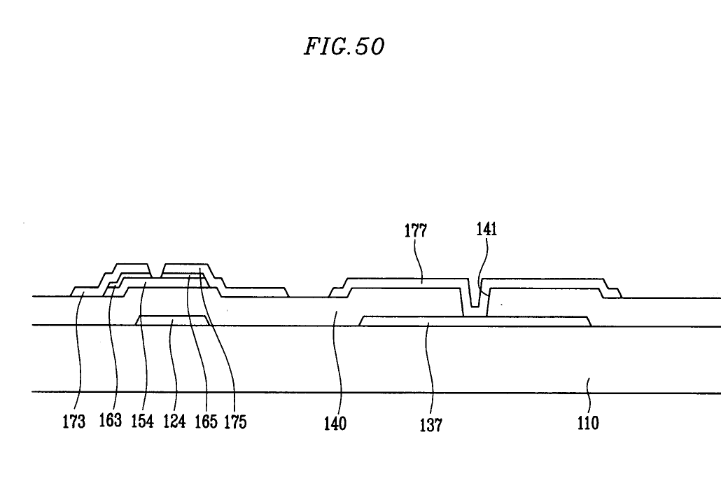

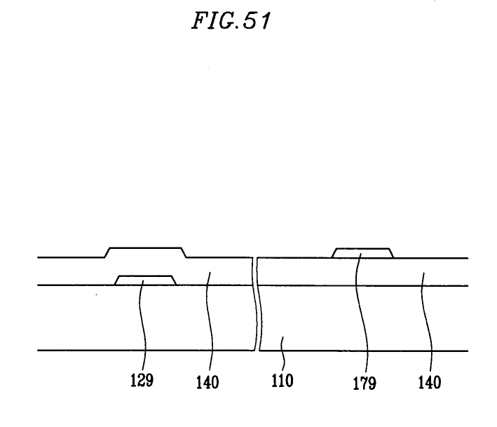

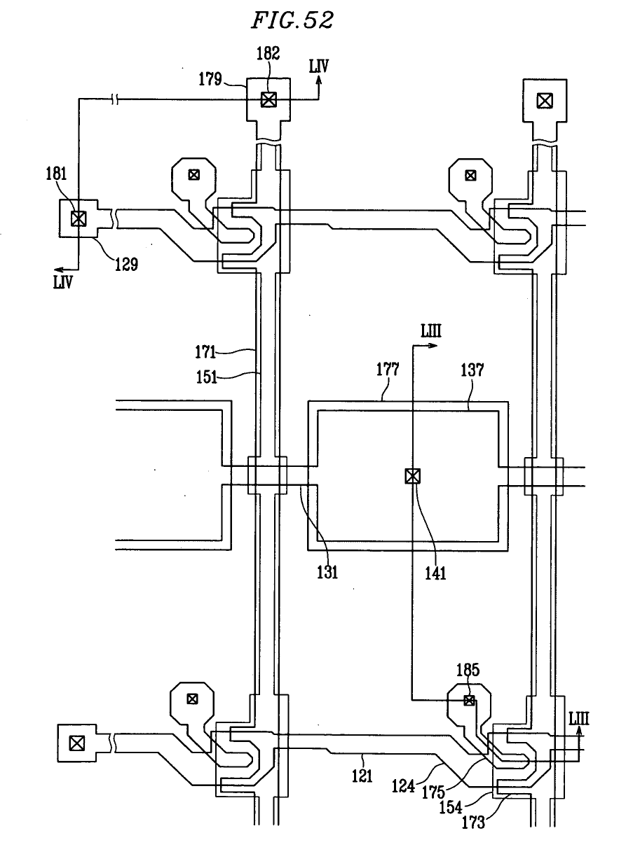

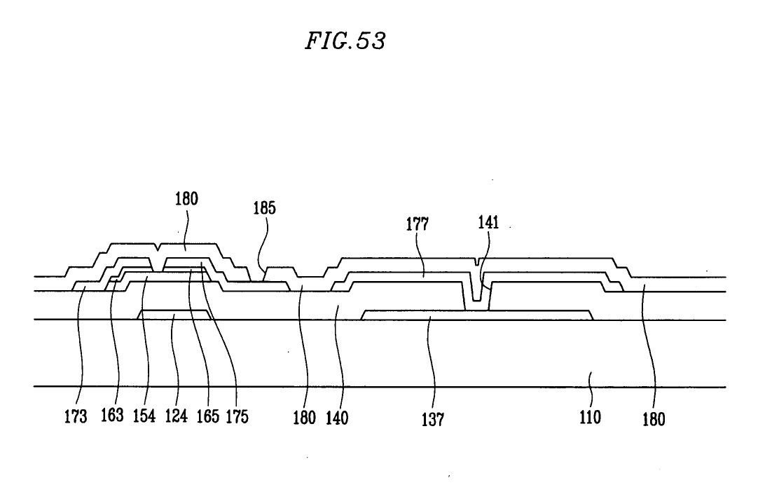

FIG. 43, FIG. 46, FIG. 49, and FIG. 52 are layout views of the TFT array panel in intermediate steps of a manufacturing method thereof according to another embodiment of the present invention, FIG. 44 and FIG. 45 are sectional views of the TFT array panel shown in FIG. 43 taken along the lines XLIV-XLIV and XLV-XLV, FIG. 47 and FIG. 48 are sectional views of the TFT array panel shown in FIG. 46 taken along the lines XLVII-XLVII and XLVIII-XLVIII, FIG. 50 and FIG. 51 are sectional views of the TFT array panel shown in FIG. 49 taken along the lines L-L and LI-LI, and FIG. 53 and FIG. 54 are sectional views of the TFT array panel shown in FIG. 52 taken along the lines LIII-LIII and LIV-LIV.

Referring to FIG. 43 to FIG. 45, a metal layer is deposited on an insulating substrate 110 by sputtering, etc., and then the metal layer is patterned by photolithography and etching to form a plurality of gate lines 121 including gate electrodes 124 and end portions 129 and a plurality of storage electrode lines 131 including storage electrodes 137.

A gate insulating layer 140 is deposited on the substrate 110, and then an intrinsic a-Si layer and an extrinsic a-Si layer are sequentially deposited on the substrate 110, and the extrinsic a-Si layer and the intrinsic a-Si layer are patterned by photolithography and etching along with the gate insulating layer 140 to form a plurality of extrinsic semiconductor stripes 161 including projections 164, a plurality of (intrinsic) semiconductor stripes 151 including projections 154, and a plurality of contact holes 141 exposing the storage electrodes 137, respectively, as shown in FIG. 46 to FIG. 48.

Referring to FIG. 49 to FIG. 51, a metal layer is deposited on the extrinsic semiconductor stripes 161 and 164 and the gate insulating layer 140, and then the metal is patterned by photolithography and etching to form a plurality of data lines 171 including source electrodes 173 and end portions 179, a plurality of drain electrodes 175, and a plurality of storage conductors 177. Thereafter, exposed portions of the extrinsic semiconductor stripes 164, which are not covered with the data lines 171 and the drain electrodes 175, are removed to complete a plurality of ohmic contact stripes 161 including projections 163 and a plurality of ohmic contact islands 165 and to expose portions of the intrinsic semiconductor stripes 151.

Next, a passivation layer 180 is deposited. Here, the thickness of the passivation layer 180 is thinner than that of the gate insulating layer 140 by about half or more. The deposited passivation layer 180 is patterned by photolithography (and etching) along with the gate insulating layer 140 to form a plurality of contact holes 181, 182, and 185 exposing the end portions 129 of the gate lines 121, the end portions 179 of the data lines 171, and the drain electrodes 175, respectively.

Finally, transparent conductor such as ITO or IZO is deposited on the substrate and patterned by photolithography and etching to form a plurality of pixel electrodes 192, and a plurality of contact assistants 81 and 82 as shown in FIG. 40 to FIG. 42.

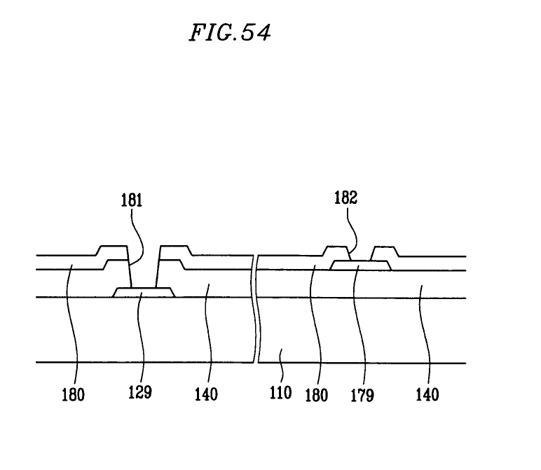

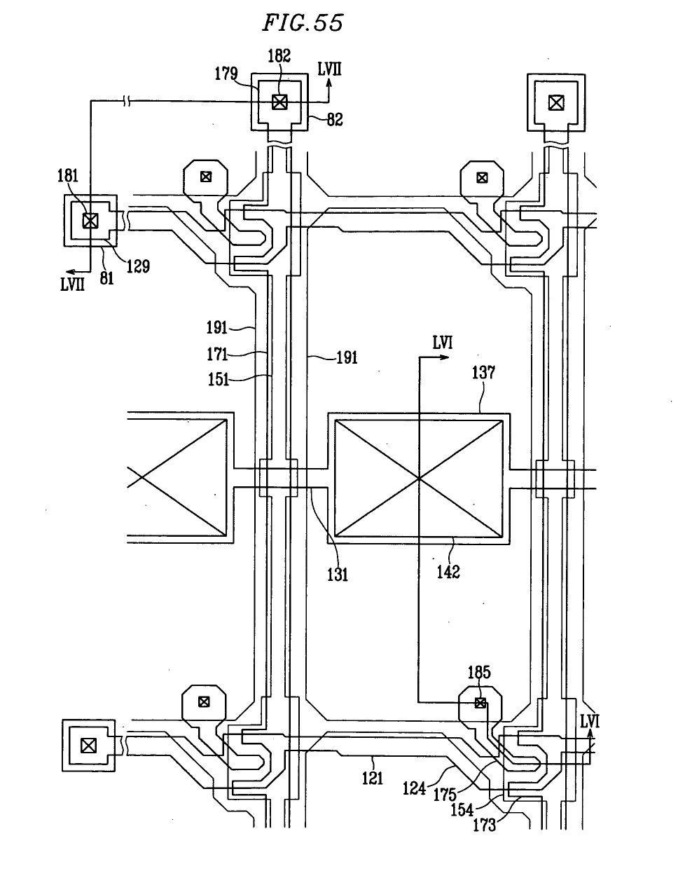

Now, a TFT array panel according to another embodiment of the present invention will be described in detail with reference to FIG. 55 to FIG. 57.

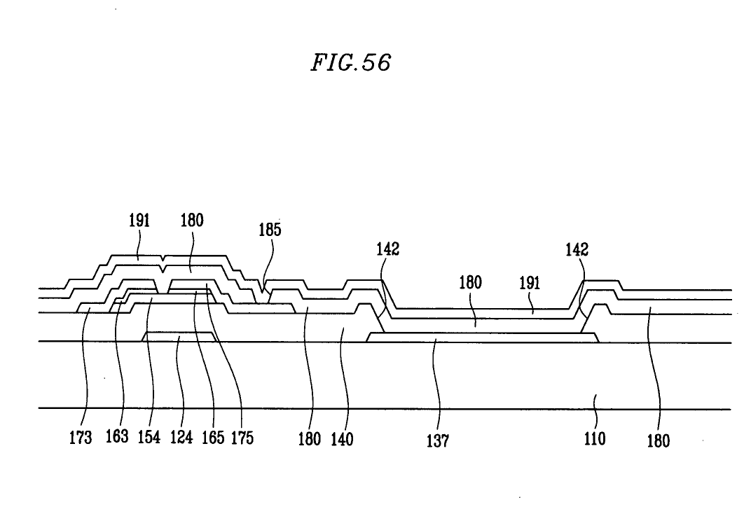

FIG. 55 is a layout view of a TFT array panel according to another embodiment of the present invention, and FIG. 56 and FIG. 57 are sectional views of the TFT array panel shown in FIG. 55 taken along the lines LVI-LVI and LVII-LVII.

As shown in FIG. 55 to FIG. 57, a layered structure of a TFT array panel according to the present embodiment is substantially similar to that shown in FIG. 40 to FIG. 42.

A plurality of gate lines 121 including gate electrodes 124 and end portions 129, and a plurality of storage electrode lines 131 including storage electrodes 137 are formed on a substrate 110. The gate insulating layer 140 having a plurality of contact holes 142 exposing the whole storage electrodes 137, a plurality of semiconductor stripes 151 including projections 154, and a plurality of ohmic contact stripes 161 including projections 163 and a plurality of ohmic contact islands 165 are sequentially formed on the gate lines 121 and the storage electrode lines 131.

A plurality of drain electrodes 175 and a plurality of data lines 171 including source electrodes 173 and end portions 179 are formed on the ohmic contacts 161 and 165 and the gate insulating layer 140, and a passivation layer 180 is formed thereon. The passivation layer 180 covers the exposed storage electrodes 137 by the contact holes 142. The passivation layer 180 may have a thickness thinner than that of the gate insulating layer 140 by about half or more.

The passivation layer 180 and the gate insulating layer 140 have a plurality of contact holes 181, 182, and 185.

A plurality of pixel electrodes 191 and a plurality of contact assistants 81 and 82 are formed on the passivation layer 180.

However, unlike the TFT array panel shown in FIG. 40 and FIG. 42, there are no the storage conductors 177 physically and electrically connected to the storage electrodes 137 through the contact holes 141. The TFT array panel according to the present embodiment includes storage electrodes wholly exposed through the contact holes 142 of the gate insulating layer 140.

In the TFT array panel according to the present embodiment, the gate insulating layer 140 has relatively large contact holes 142 exposing the whole storage electrodes 137, and the storage electrodes 137 exposed through contact holes 142 overlap the pixel electrodes 191 to form storage capacitors along with the passivation layer 180 sandwiched therebetween.

Accordingly, the storage capacitor of the TFT array panel according to present embodiment may have a higher electrical capacity than the known storage capacitor even though the storage conductor 177 has the same area as the storage electrode of the known storage capacitor including the pixel electrode and the storage electrode overlapping each other, and the gate insulating layer sandwiched therebetween.

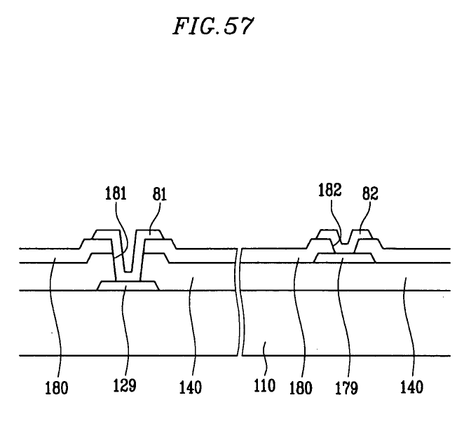

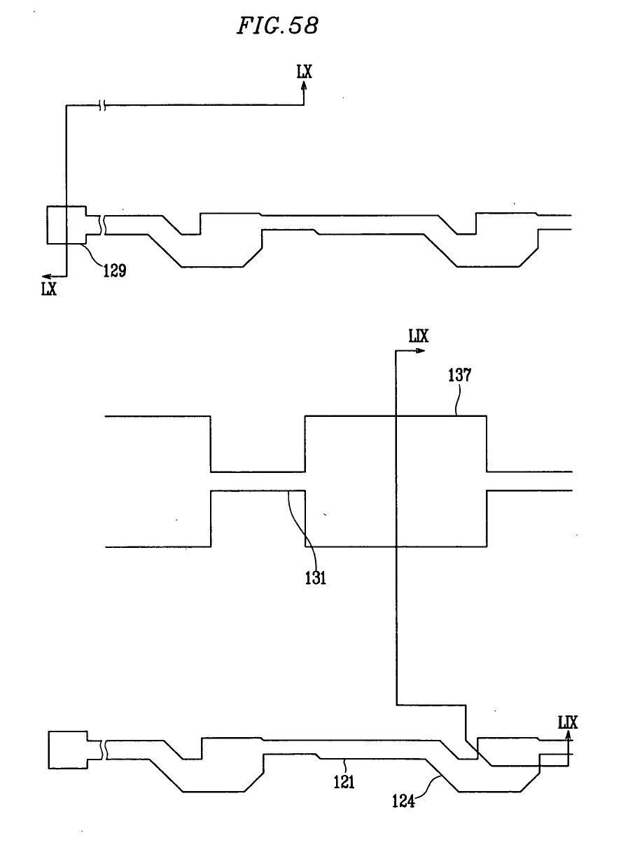

Now, a manufacturing method of the TFT array panel shown FIG. 55 to FIG. 57 according to the present embodiment will be described in detail with reference to FIG. 58 to FIG. 69.

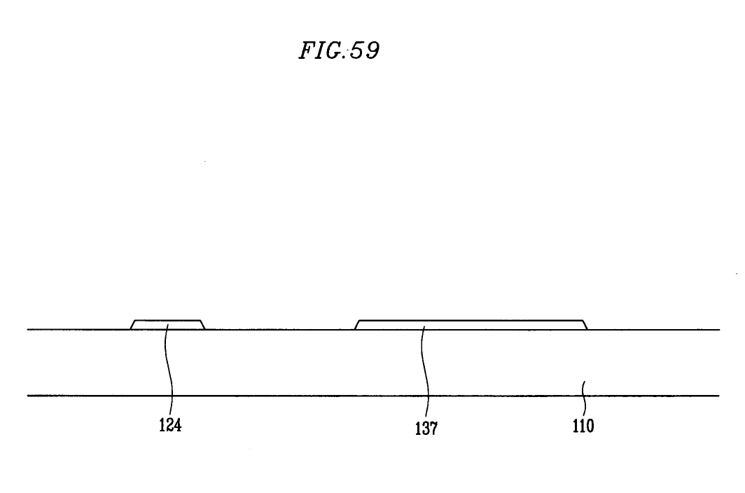

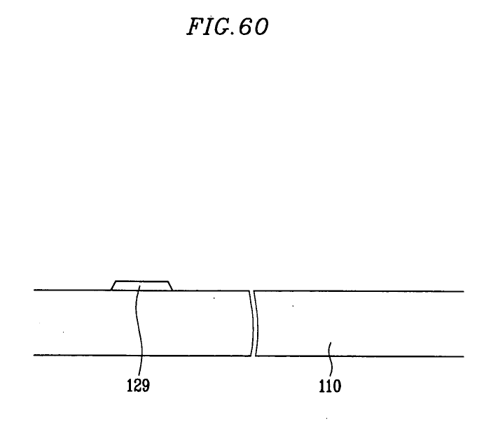

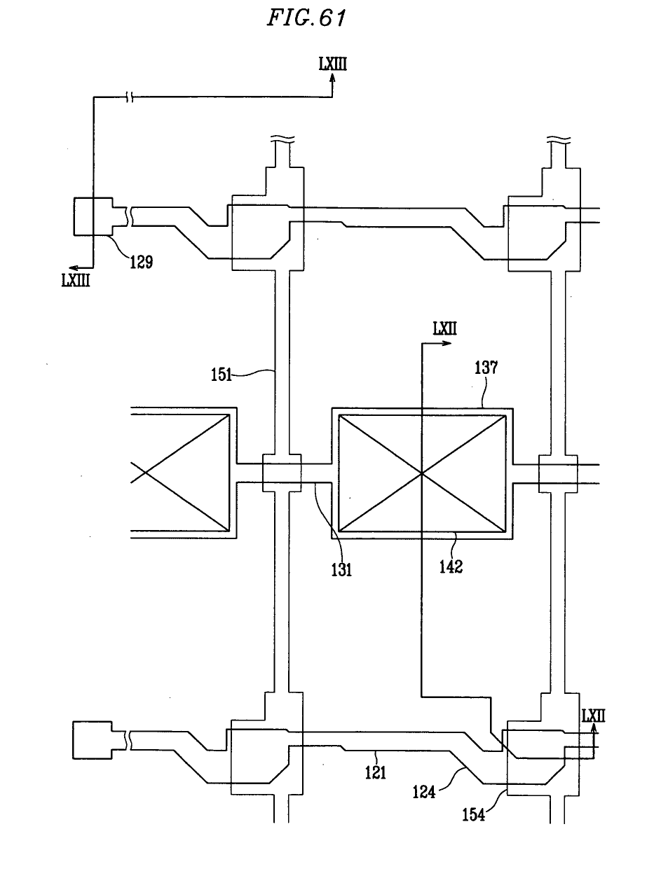

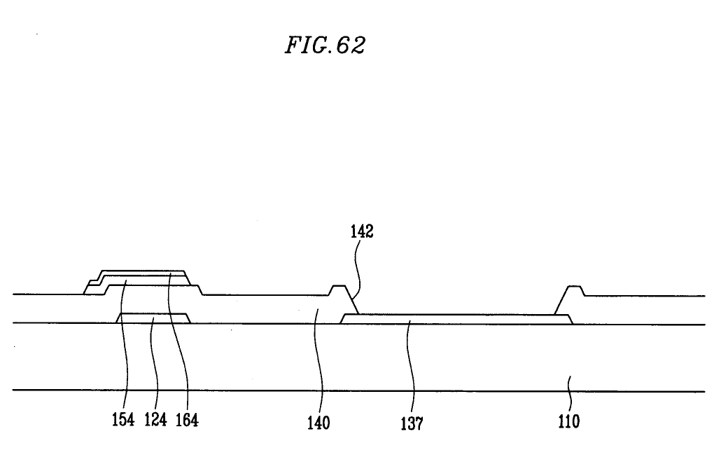

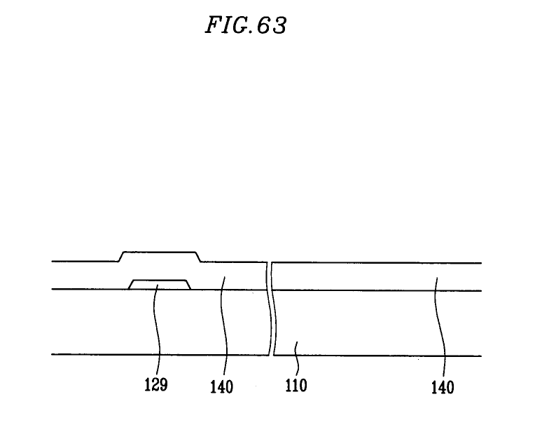

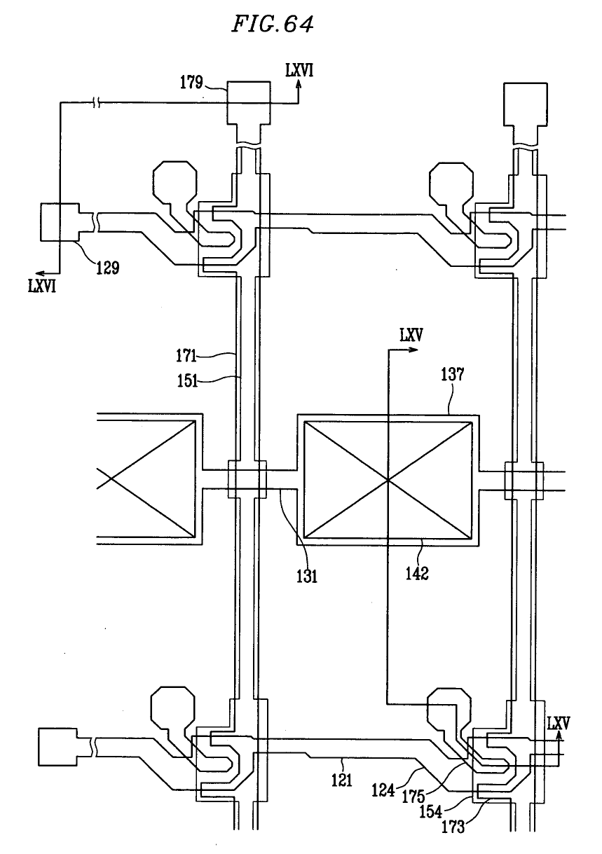

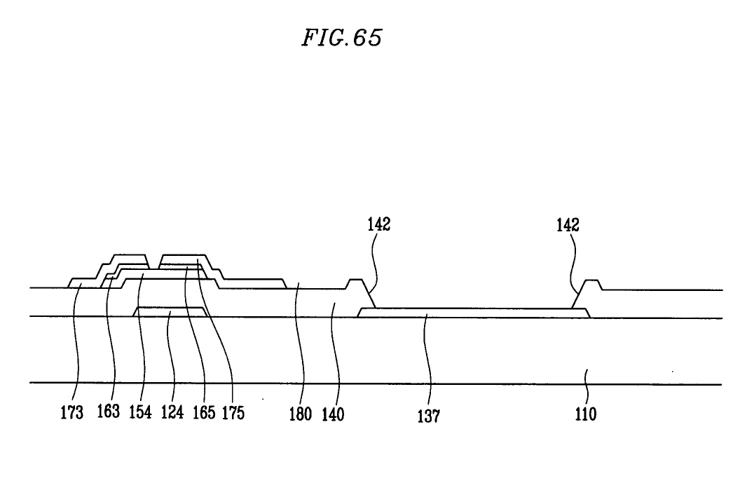

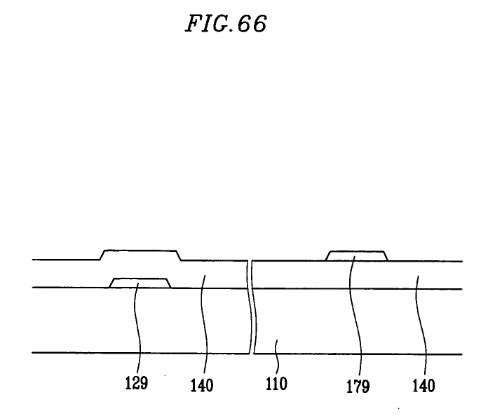

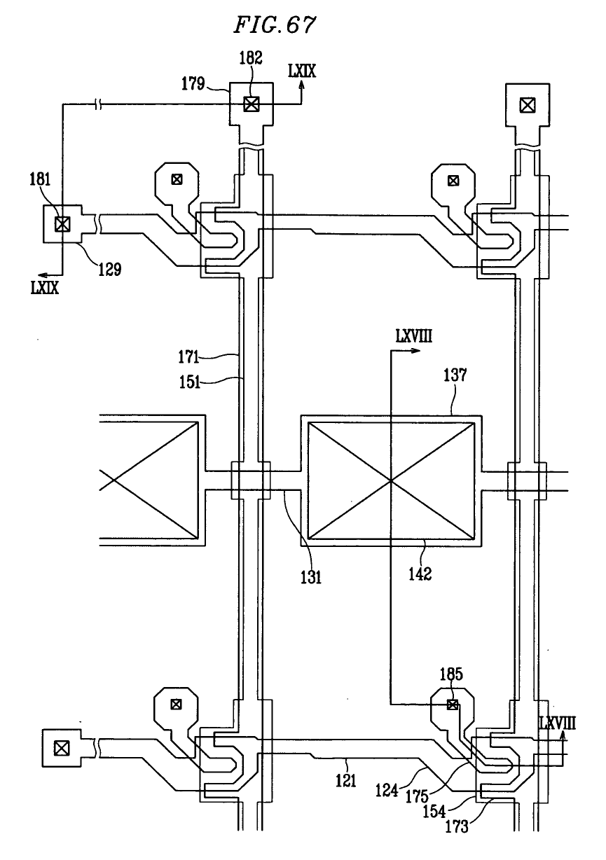

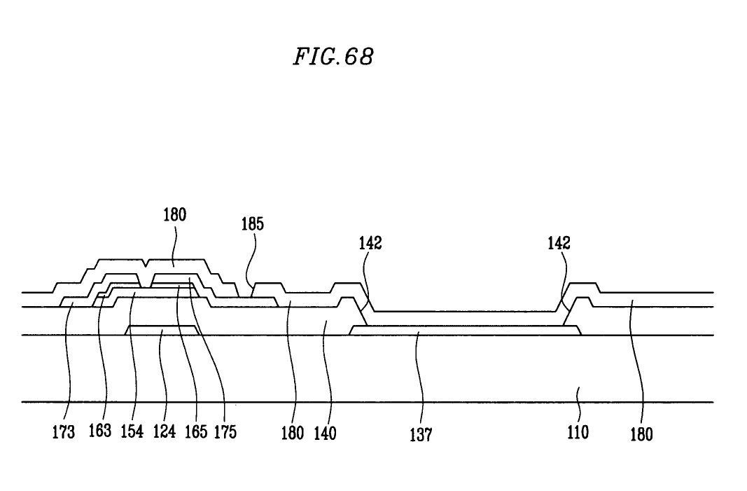

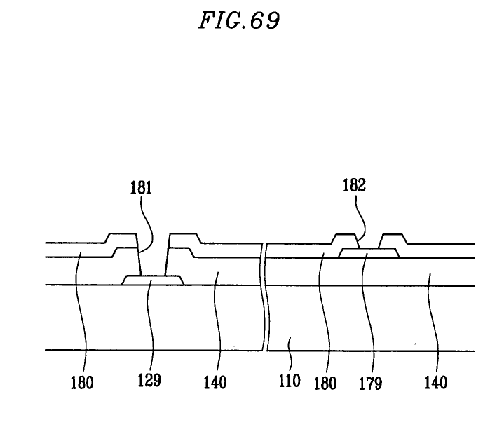

FIG. 58, FIG. 61, FIG. 64, and FIG. 67 are layout views of the TFT array panel in intermediate steps of a manufacturing method thereof according to another embodiment of the present invention, FIG. 59 and FIG. 60 are sectional views of the TFT array panel shown in FIG. 58 taken along the lines LIX-LIX and LX-LX, FIG. 62 and FIG. 63 are sectional views of the TFT array panel shown in FIG. 61 taken along the lines LXII-LXII and LXIII-LXIII, FIG. 65 and FIG. 66 are sectional views of the TFT array panel shown in FIG. 64 taken along the lines LXV-LXV and LXVI-LXVI, and FIG. 68 and FIG. 69 are sectional views of the TFT array panel shown in FIG. 67 taken along the lines LXVIII-LXVIII and LXIX-LXIX.

As shown in FIG. 58 to FIG. 60, a plurality of gate lines 121 including gate electrodes 124 and end portions 129 and a plurality of storage electrode lines 131 including storage electrodes 137 are formed on a substrate 110.

A gate insulating layer 140 is deposited on the substrate 110, and then an intrinsic a-Si layer and an extrinsic a-Si layer are sequentially deposited on the substrate 110 and the extrinsic a-Si layer and the intrinsic a-Si layer are patterned by photolithography and etching along with the gate insulating layer 140 to form a plurality of extrinsic semiconductor stripes 161 including projections 164 and a plurality of (intrinsic) semiconductor stripes 151 including projections 154, and a plurality of contact holes 142 exposing the whole storage electrodes 137, respectively, as shown in FIG. 61 to FIG. 63.

Referring to FIG. 64 to FIG. 66, a plurality of data lines 171 including source electrodes 173 and end portions 179, and a plurality of drain electrodes 175 are formed on the extrinsic semiconductor stripes 161 and 164, and thereafter, exposed portions of the extrinsic semiconductor stripes 164, which are not covered with the data lines 171 and the drain electrodes 175, are removed to complete a plurality of ohmic contact stripes 161 including projections 163 and a plurality of ohmic contact islands 165 and to expose portions of the intrinsic semiconductor stripes 151.

Next, a passivation layer 180 is deposited. Here, the thickness of the passivation layer 180 is thinner than that of the gate insulating layer 140 by about half or more.

The deposited passivation layer 180 is patterned by photolithography (and etching) along with the gate insulating layer 140 to form a plurality of contact holes 181, 182, and 185 exposing the end portions 129 of the gate lines 121, the end portions 179 of the data lines 171, and the drain electrodes 175, respectively.

Finally, a plurality of pixel electrodes 192, and a plurality of contact assistants 81 and 82 are formed on the passivation layer 180 as shown in FIG. 55 to FIG. 57.

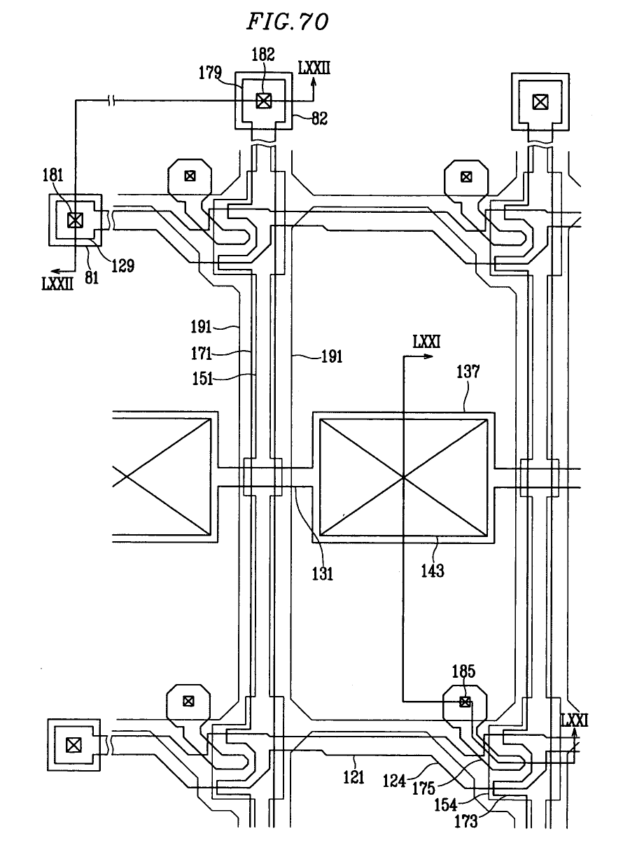

Next, a TFT array panel according to another embodiment of the present invention will be described in detail with reference to FIG. 70 to FIG. 72.

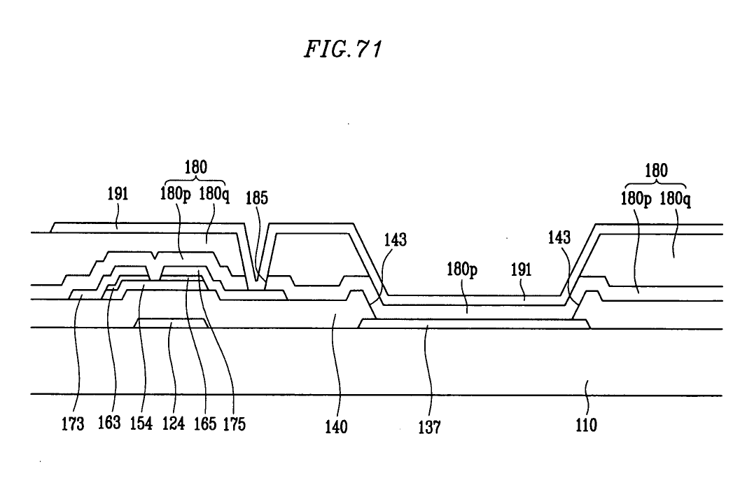

FIG. 70 a layout view of a TFT array panel according to another embodiment of the present invention, and FIG. 71 and FIG. 72 are sectional views of the TFT array panel shown in FIG. 70 taken along the lines LXXI-LXXI and LXXII-LXXII.

The layered structure of a TFT array panel according to the present embodiment is substantially similar to that shown in FIG. 55 to FIG. 57.

A plurality of gate lines 121 including gate electrodes 124 and end portions 129, and a plurality of storage electrode lines 131 including storage electrodes 137 are formed on a substrate 110.

A gate insulating layer 140 having a plurality of contact holes 142 exposing the whole storage electrodes 137, a plurality of semiconductor stripes 151 including projections 154, and a plurality of ohmic contact stripes 161 including projections 163 and a plurality of ohmic contact islands 165 are sequentially formed on the gate lines 121 and the storage electrode lines 131.

A plurality of drain electrodes 175 and a plurality of data lines 171 including source electrodes 173 and end portions 179 are formed on the ohmic contacts 161 and 165 and the gate insulating layer 140. A passivation layer 180 is formed thereon.

However, unlike the TFT array panel shown in FIG. 55 to FIG. 57, the passivation layer 180 has a double-layered structure including a lower layer 180p and an upper layer 180q. The upper layer 180q is thicker than the lower layer 180p, and has a flat surface. The upper layer 180q disposed over the storage electrodes 137 is eliminated.

The lower layer 180p may be made of an inorganic insulator such as silicon nitride or silicon oxide and the upper layer 180q may be made of an organic insulator.

The passivation layer 180 and the gate insulating layer 140 have a plurality of contact holes 181, 182, and 185.

A plurality of pixel electrodes 191 and a plurality of contact assistants 81 and 82 are formed on the upper layer 180q or the lower layer 180p of the passivation layer 180.

In the TFT array panel according to the present embodiment, the storage electrodes 137 exposed through the contact holes 142 overlap the pixel electrodes 191 to form storage capacitors along with the lower layer 180p of the passivation layer 180 sandwiched therebetween.

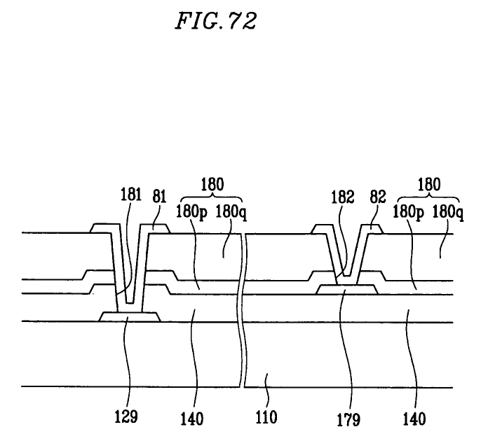

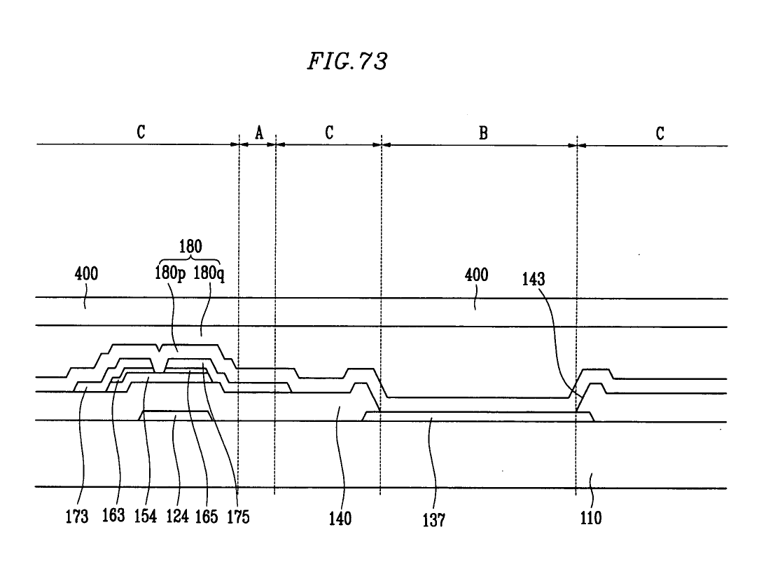

Now, a manufacturing method of the TFT array panel according to the present embodiment will be described in detail with reference to FIG. 73 to FIG. 82.

A manufacturing method of the TFT array panel shown in FIG. 70 to FIG. 72 according to the present embodiment is substantially similar to that of the TFT array panel shown in FIG. 55 to FIG. 57 according to the previous embodiment.

A plurality of gate lines 121 including gate electrodes 124 and end portions 129 and a plurality of storage electrode lines 131 including storage electrodes 137 are formed on a substrate 110, a gate insulating layer 140 is deposited on the substrate 110, and then an intrinsic a-Si layer and an extrinsic a-Si layer are sequentially deposited on the substrate 110 and the extrinsic a-Si layer and the intrinsic a-Si layer are patterned by photolithography and etching along with the gate insulating layer 140 to form a plurality of extrinsic semiconductor stripes 161 including projections 164 and a plurality of (intrinsic) semiconductor stripes 151 including projections 154, and a plurality of contact holes 142 exposing the whole storage electrodes 137, respectively.

A plurality of data lines 171 including source electrodes 173 and end portions 179, and a plurality of drain electrodes 175 are formed on the extrinsic semiconductor stripes 161 and 164, and thereafter, exposed portions of the extrinsic semiconductor stripes 164, which are not covered with the data lines 171 and the drain electrodes 175, are removed to complete a plurality of ohmic contact stripes 161 including projections 163 and a plurality of ohmic contact islands 165 and to expose portions of the intrinsic semiconductor stripes 151.

A passivation layer 180 is deposited. The deposited passivation layer 180 is patterned by photolithography (and etching) along with the gate insulating layer 140 to form a plurality of contact holes 181, 182, and 185 exposing the end portions 129 of the gate lines 121, the end portions 179 of the data lines 171, and the drain electrodes 175, respectively, and simultaneously the upper layer 180q of the passivation layer 180 disposed over the storage electrodes 137 is eliminated. A method to form such a structure will now be described with reference to FIG. 73 to FIG. 82. FIG. 73 to FIG. 82 are sectional views of the TFT array panel shown in FIG. 70 to FIG. 72 in intermediate steps of a manufacturing method thereof according to another embodiment of the present invention.

Referring to FIG. 73 and FIG. 74, the lower layer 180p and the upper layer 180q of the passivation layer 180 are deposited on the substrate 110, and a photoresist film 400 is deposited on the upper layer 180q of the passivation layer 180.

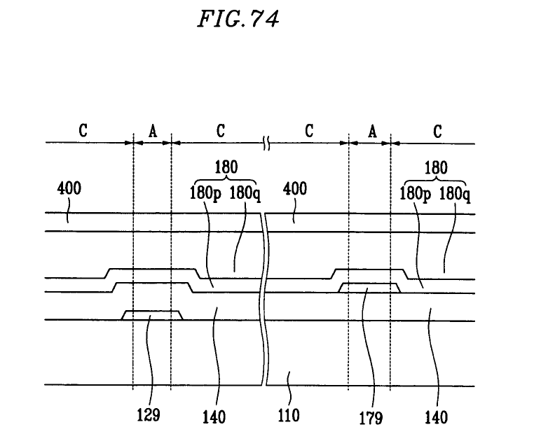

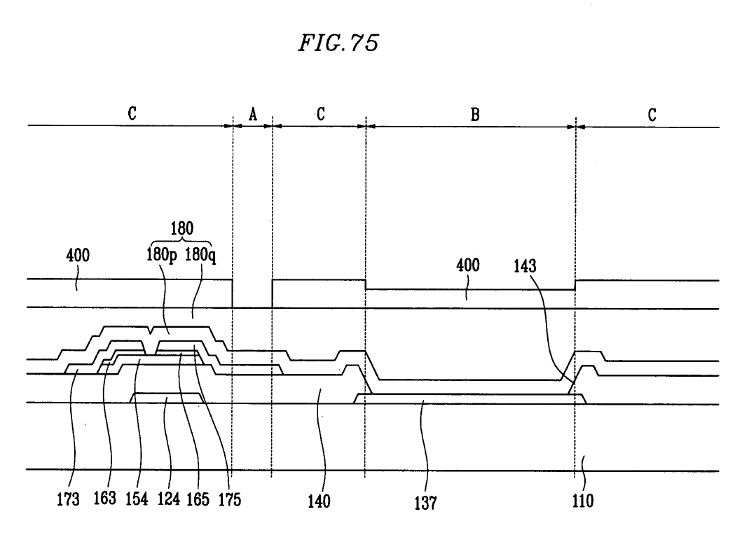

The photoresist film 400 is exposed to light through a photo-mask (not shown), and developed such that the developed photoresist has a position-dependent thickness A, B, and C as shown in FIG. 75 and FIG. 76.

The position-dependent thickness of the photoresist patterns is obtained by several techniques, for example, by providing translucent areas B on the photo mask as well as light transmitting transparent areas A and light blocking opaque areas C.

The translucent areas may have a slit pattern, a lattice pattern, or comprise thin film(s) having intermediate transmittance or intermediate thickness. When using a slit pattern, it is preferable that the width of the slits or the distance between the slits be smaller than the resolution of a light exposer used for the photolithography.

As shown in FIG. 75 and FIG. 76, the photoresist film disposed in area A may be eliminated completely, the photoresist film disposed in area B may be half eliminated, and the photoresist film disposed in area C may not eliminated.

The thickness ratio of the photoresist film disposed in area B to the photoresist film disposed in area C is adjusted depending upon the process conditions in the subsequent process steps. It is preferable that the thickness of the photoresist film disposed in area B is equal to or less than half of the thickness of the photoresist film disposed in area C.

Another example is to use a reflowable photoresist. In detail, once a photoresist pattern made of a reflowable material is formed by using a normal exposure mask with only transparent areas and opaque areas, it is subject to a reflow process to flow onto areas without the photoresist, thereby forming thin portions.

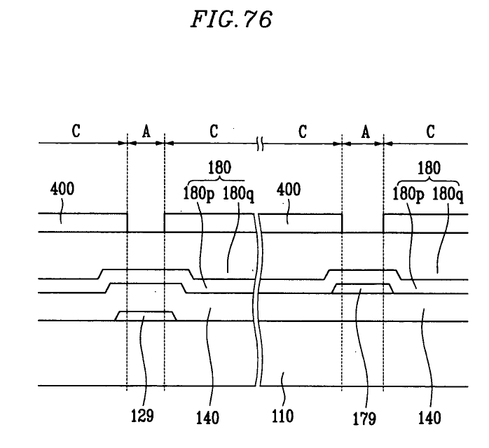

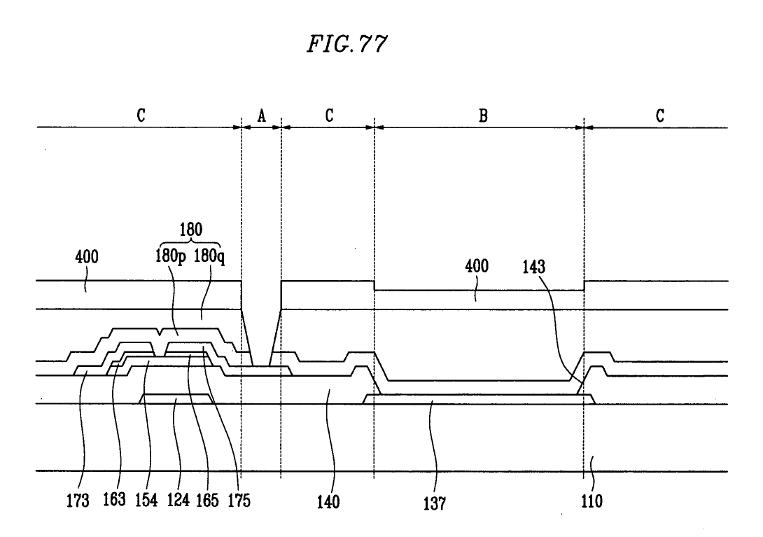

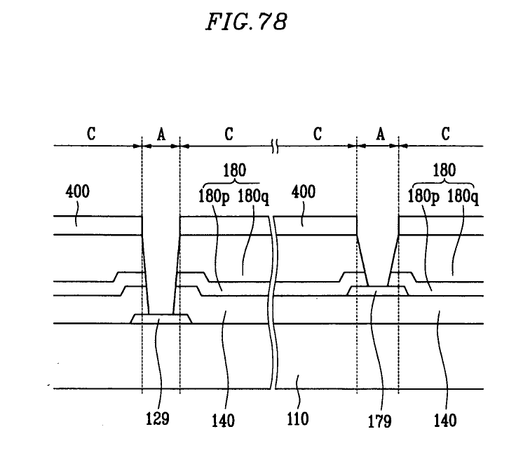

Next, the upper layer 180q and lower layer 180p of the passivation layer 180, and gate insulating layer 140 are etched using the photoresist film 400 as a mask to form the plurality of contact holes 181, 182, and 185 exposing the end portions 129 of the gate lines 121, the end portions 179 of the data lines 171, and the drain electrodes 175, respectively as shown in FIG. 77 and FIG. 78.

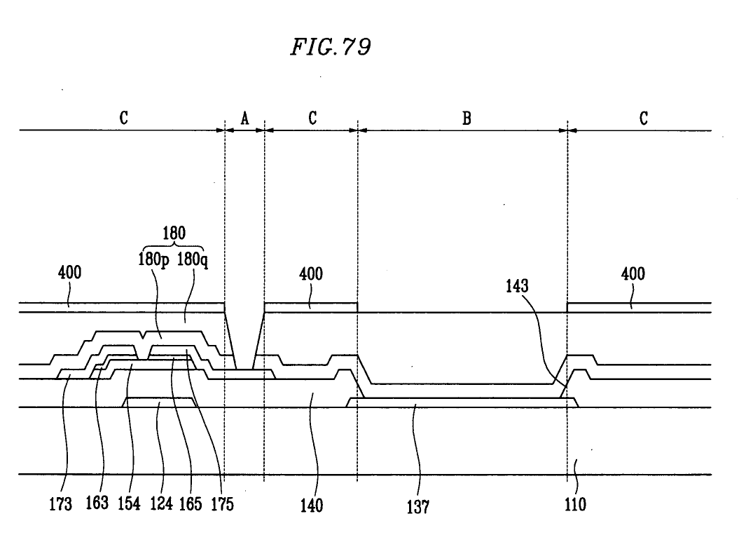

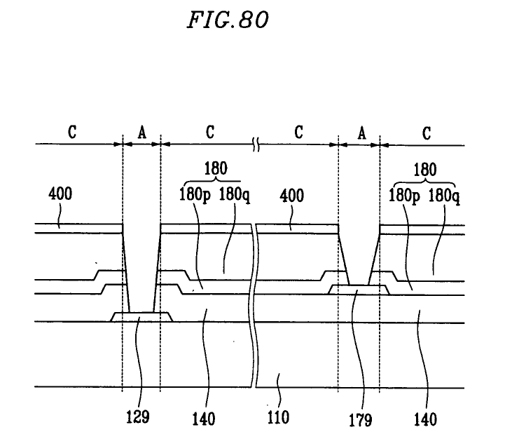

Next, as shown in FIG. 79 and FIG. 80, an ashing is performed on the photoresist film 400 such that the photoresist film disposed in area B is all eliminated and the thickness of the photoresist film disposed in area C is reduced.

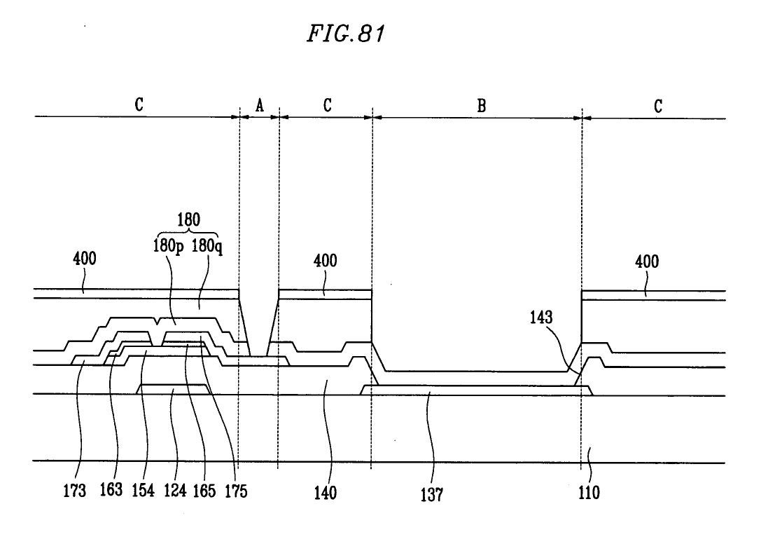

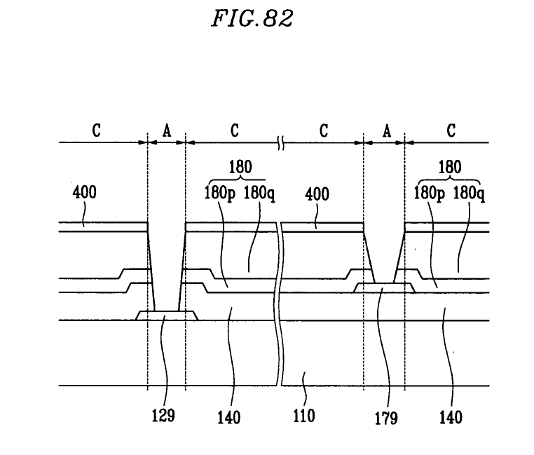

Referring to FIG. 81 and FIG. 82, the upper layer 180q of the passivation layer 180 is etched using the remaining photoresist film disposed in area C as a mask such that the upper layer 180q disposed over the storage electrodes is eliminated and the lower layer 180p remains over the storage electrodes.

Finally, the remaining photoresist film disposed in area C is eliminated by ashing, etc.

As described above, in the manufacturing method of the TFT array panel according to the present embodiment, the upper layer 180q and the lower layer 180p of the passivation layer 180 are patterned by photolithography and etching using one photo-mask along with the gate insulating layer 140 to form a plurality of contact holes 181, 182, and 185 exposing the end portions 129 of the gate lines 121, the end portions 179 of the data lines 171, and the drain electrodes 175, respectively, and simultaneously the upper layer 180q of the passivation layer 180 disposed over the storage electrodes 137 is eliminated.

Next, a plurality of pixel electrodes 191 and a plurality of contact assistants 81 and 82 are formed as shown in FIG. 70 to FIG. 72.

As described above, the TFT array panels according to embodiments of the present invention include the storage capacitor including two conductors overlapping each other, and the passivation layer 180 sandwiched therebetween.

Accordingly, the storage capacitor of the TFT array panel according to an embodiment of the present invention may have a higher electrical capacity than the known storage capacitor even though the storage conductors have the same area as the storage electrode of the known storage capacitor.

In the above embodiments, many films are described as having a single layer, however they may have a double-layered structure or a triple-layered structure.

In the above embodiments, the TFT array panels are described as being used in an LCD, however they may be applied to other display panels including TFTs, for example, organic light emitting diode (OLED) display, etc.

While this invention has been described in connection with what is presently considered to be practical exemplary embodiments, it is to be understood that the invention is not limited to the disclosed embodiments, but, on the contrary, is intended to cover various modifications and equivalent arrangements included within the spirit and scope of the appended claims.

What is claimed is:

1. A thin film transistor array panel, comprising:
a substrate;
a gate line including a gate electrode, and a storage electrode line including a storage electrode formed on the substrate;
a gate insulating layer formed on the gate line, the storage electrode line, and the substrate;
a semiconductor layer formed on the gate insulating layer;
a data line and a drain electrode formed on the semiconductor layer and the gate insulating layer;
a storage conductor formed on the gate insulating layer, made of the same layer as the data line and separated from the data line, and electrically connected to the storage electrode using a connecting member;
a passivation layer formed on the data line, the drain electrode, and the storage conductor; and
a transparent electrode formed on the passivation layer and connected to the drain electrode.

2. The TFT array panel of claim 1, wherein the gate insulating layer is thicker than the passivation layer, and
the transparent electrode and the storage conductor overlapping each other form a storage capacitor along with the passivation layer sandwiched therebetween.

3. The TFT array panel of claim 2, wherein the storage conductor is supplied with a storage voltage through the storage electrode.

4. The TFT array panel of claim 1, wherein the passivation layer has a hole exposing a portion of the storage conductor.

5. The TFT array panel of claim 1, further comprising
an organic insulator formed on a portion of the transparent electrode; and
a reflective electrode formed on the organic insulator.

6. The TFT array panel of claim 5, wherein the reflective electrode is physically and electrically connected to the transparent electrode at the edge of the organic insulator.

7. The TFT array panel of claim 6, wherein the storage conductor is disposed in a region including the reflective electrode.

8. A TFT array panel, comprising:
a substrate;
a gate line including a gate electrode and formed on the substrate;
a gate insulating layer formed on the gate line and the substrate;
a semiconductor layer formed on the gate insulating layer;
a data line, a drain electrode, and a storage electrode line including a storage electrode formed on the semiconductor layer and the gate insulating layer;
a passivation layer formed on the data line, the drain electrode, and the storage electrode line; and
a transparent electrode formed on the passivation layer and connected to the drain electrode.

9. The TFT array panel of claim 8, wherein the storage electrode line extends substantially parallel to the date line.

10. The TFT array panel of claim 8, wherein the gate insulating layer is thicker than the passivation layer, and the transparent electrode and the storage electrode line including the storage electrode overlap each other to form a storage capacitor along with the passivation layer sandwiched there between.

11. The TFT array panel of claim 10, wherein the storage electrode line is supplied with a storage voltage.

12. The TFT array panel of claim 8, further comprising
an organic insulator formed on a portion of the transparent electrode; and a reflective electrode formed on the organic insulator.

13. The TFT array panel of claim 12, wherein the reflective electrode is physically and electrically connected to the transparent electrode at the edge of the organic insulator.

14. The TFT array panel of claim 12, wherein the storage conductor is disposed in a region including the reflective electrode.

15. A method of manufacturing a TFT array panel, comprising:
forming a gate line including a gate electrode and a storage electrode line including a storage electrode on a substrate;
forming a gate insulating layer on the gate line, the storage electrode line, and the substrate;
forming a semiconductor layer on the gate insulating layer;
forming a data line, a drain electrode, and a storage conductor on the gate insulating layer and the semiconductor layer;
forming a passivation layer on the data line, the drain electrode, and the storage conductor; and
forming a pixel electrode connected to the drain electrode on the passivation layer.

16. The method of claim 15, further comprising:
forming a hole in the passivation layer exposing the storage conductor;
forming a contact hole in the gate insulating layer exposing the storage electrode ; and
forming a connecting member electrically connecting the storage conductor to the storage electrode through the contact hole.

17. The method of claim 16, wherein forming of the pixel electrode and forming of the connecting member are performed simultaneously.

18. A manufacturing method of a TFT array panel, comprising:
forming a gate line including a gate electrode on a substrate;
forming a gate insulating layer on the gate line and the substrate;
forming a semiconductor layer on the gate insulating layer;
forming a data line, a drain electrode, and a storage electrode line including a storage electrode on the gate insulating layer and the semiconductor layer;
forming a passivation layer on the data line, the drain electrode, and the storage electrode line; and
forming a pixel electrode connected to the drain electrode on the passivation layer.

19. The method of claim 18, wherein the gate insulating layer is thicker than the passivation layer, and the pixel electrode and the storage electrode line including the storage electrode overlap each other to form a storage capacitor along with the passivation layer sandwiched therebetween.

20. The method of the claim 18, further comprising
forming an organic insulator on a portion of the pixel electrode; and
forming a reflective electrode on the organic insulator.

21. A TFT array panel, comprising:
a substrate;
a gate line including a gate electrode and a storage electrode line including a storage electrode formed on the substrate;
a gate insulating layer formed on the gate line, the storage electrode, and the substrate and having a contact hole exposing the storage electrode;
a semiconductor layer formed on the gate insulating layer;
a data line and a drain electrode formed on the semiconductor layer and the gate insulating layer;
a storage conductor formed on the gate insulating layer, made of the same layer as the data line and separated from the data line, and electrically connected to the storage electrode through the contact hole of the gate insulating layer;
a passivation layer formed on the data line, the drain electrode, and the storage conductor; and
a pixel electrode formed on the passivation layer and connected to the drain electrode.

22. The TFT array panel of claim 21, wherein the storage electrode line is supplied with a storage voltage.

23. The TFT array panel of claim 22, wherein the storage conductor is supplied with a storage voltage through the storage electrode.

24. The TFT array panel of claim 23, wherein the gate insulating layer is thicker than the passivation layer, and the pixel electrode and the storage conductor overlap each other to form a storage capacitor along with the passivation layer sandwiched therebetween.

25. The TFT array panel of claim 21, wherein the passivation layer has a contact hole exposing the drain electrode, and the pixel electrode is electrically connected to the drain electrode through the contact hole.

26. A method of manufacturing a TFT array panel, comprising:
forming a gate line including a gate electrode and a storage electrode line including a storage electrode on a substrate;
forming a gate insulating layer on the gate line, the storage electrode line, and the substrate;
depositing an intrinsic amorphous silicon layer on the gate insulating layer;
depositing an extrinsic amorphous silicon layer on the intrinsic amorphous silicon layer;
patterning the extrinsic amorphous silicon layer and the intrinsic amorphous silicon layer along with the gate insulating layer to form an extrinsic semiconductor pattern, an intrinsic semiconductor pattern, and a first contact hole in the gate insulating layer exposing a portion of the storage electrode;
forming a data line and a drain electrode on the gate insulating layer and the extrinsic semiconductor pattern and, simultaneously forming a storage conductor connected to the storage electrode through the first contact hole;
forming a passivation layer having a second contact hole exposing the drain electrode on the data line, the drain electrode, and the storage conductor; and
forming a pixel electrode connected to the drain electrode through the second contact hole on the passivation layer.

27. The method of claim 26, wherein the gate insulating layer is thicker than the passivation layer, and the pixel electrode and the storage conductor overlap each other to form a storage capacitor along with the passivation layer sandwiched therebetween.

28. A TFT array panel, comprising:
a substrate;
a gate line including a gate electrode, and a storage electrode line including a storage electrode formed on the substrate;
a gate insulating layer formed on the gate line, the storage electrode line, and the substrate and having a contact hole exposing the whole storage electrode;
a semiconductor layer formed on the gate insulating layer;
a data line and a drain electrode formed on the semiconductor layer and the gate insulating layer;
a passivation layer formed on the data line and the drain electrode; and
a pixel electrode connected to the drain electrode and formed on the passivation layer, wherein
the pixel electrode and the storage electrode overlap each other to form a storage capacitor along with the passivation layer sandwiched therebetween.

29. The TFT array panel of claim 28, wherein the storage electrode line is supplied with a storage voltage.

30. The TFT array panel of claim 29, wherein the gate insulating layer is thicker than the passivation layer.

31. The TFT array panel of claim 28, wherein the passivation has a double-layered structure including a lower layer and an upper layer, and the upper layer is thicker than the lower layer.

32. The TFT array panel of claim 31, wherein the upper layer of the passivation layer is eliminated over the storage electrode.

33. The TFT array panel of claim 31, wherein the lower layer comprises an inorganic insulator, and the upper layer comprises an organic insulator.

34. A manufacturing method of a TFT array panel, comprising:
forming a gate line including a gate electrode and a storage electrode line including a storage electrode on a substrate;
forming a gate insulating layer on the gate line, the storage electrode line, and the substrate;
depositing an intrinsic amorphous silicon layer on the gate insulating layer;
depositing an extrinsic amorphous silicon layer on the intrinsic amorphous silicon layer;
patterning the extrinsic amorphous silicon layer and the intrinsic amorphous silicon layer along with the gate insulating layer to form an extrinsic semiconductor pattern, an intrinsic semiconductor pattern, and a first contact hole in the gate insulating layer exposing a portion of the storage electrode;
forming a data line and a drain electrode on the gate insulating layer and the extrinsic semiconductor pattern;
forming a passivation layer having a second contact hole exposing the drain electrode on the data line and the drain electrode; and
forming a pixel electrode connected to the drain electrode through the second contact hole on the passivation layer.

35. The method of claim 34, wherein the thickness of the gate insulating layer is greater than of the passivation layer.

36. The method of claim 34, wherein the passivation layer has a double-layered structure including a lower layer and an upper layer, wherein the upper layer is thicker than the lower layer, and the upper layer of is eliminated over the storage electrode.

37. The method of claim 36, wherein forming the passivation layer comprises:
depositing a lower passivation layer on the substrate;
depositing an upper passivation layer on the lower passivation layer;
forming photoresist patterns having a position-dependent thickness and exposing a portion of the upper passivation layer;
etching the upper passivation layer, the lower passivation layer, and the gate insulating layer to form a second contact hole, a third contact hole, and a fourth contact hole exposing the gate line, the data line, and the drain electrode, respectively;
reducing the height of the photoresist patterns to expose the upper passivation layer over the storage electrode;
etching the upper passivation layer using the reduced photoresist patterns as a mask to eliminate the upper passivation layer; and
eliminating the reduced photoresist patterns, wherein the thickness of the gate insulating layer is thicker than that of the lower passivation layer.
